(19) United States
(12) Patent Application Publication
(10) Pub. No.: US 2003/0068572 A1
(43) Pub. Date: Apr. 10, 2003

(54) Multicolor image-forming material

(75) Inventors: Yasutomo Goto, Shizuoka (JP); Susumu Sugiyama, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/097,980

(22) Filed: Mar. 15, 2002

(30) Foreign Application Priority Data
Mar. 16, 2001 (JP) P2001-076625
Mar. 19, 2001 (JP) P2001-078846
Mar. 19, 2001 (JP) P2001-079363
Mar. 19, 2001 (JP) P2001-079555
Feb. 25, 2002 (JP) P2002-047930

(51) Int. Cl. G03F 7/34

(52) U.S. Cl. 430/200; 430/253; 430/256; 430/259

(57) ABSTRACT

A multicolor image-forming material of recording an image using an image-receiving sheet comprising a support having thereon at least an image-receiving layer, and thermal transfer sheets for forming four or more different colors each comprising a support having thereon at least a light-to-heat conversion layer and an image-forming layer, said image being recorded by superposing each said thermal transfer sheet and said image-receiving sheet such that the image-forming layer of the thermal transfer sheet and the image-receiving layer of the image-receiving layer come to face each other, irradiating laser light and transferring the image-forming layer in the region irradiated with the laser light onto the image-receiving layer of the image-receiving sheet, wherein the adhesive tape peeling strength on the image-receiving layer surface of said image-receiving sheet is from 800 to 20,000 mN/cm at room temperature.

### FIELD OF THE INVENTION

The present invention relates to a multicolor image-forming material and a multicolor image formation method for forming a high-resolution full color image using laser light. More specifically, the present invention relates to a multicolor image-forming material useful for manufacturing a color proof (DDCP (direct digital color proof)) or a mask image in the printing field from digital image signals by laser recording.

### BACKGROUND OF THE INVENTION

In the field of graphic art, an image is printed on a printing plate using a set of color-separation films prepared from a color original by using lithographic films. In general, a color proof is manufactured from the color-separation films before the main printing (i.e., actual printing operation) so as to check on errors in the color separation process or whether color correction and the like are necessary. The color proof is demanded to realize high resolution for enabling the formation of a halftone image with high reproducibility and to have capabilities such as high processing stability. Furthermore, in order to obtain a color proof approximated to an actual printed matter, the materials used for the color proof are preferably the materials actually used for the printed matter, for example, the substrate is preferably the printing paper and the coloring material is preferably the pigment. As for the method for manufacturing the color proof, a dry process of using no developer solution is highly demanded.

For manufacturing the color proof by a dry process, a recording system of manufacturing a color proof directly from digital signals has been developed accompanying the recently widespread electronic system in the pre-printing process (pre-press field). This electronic system is developed particularly for the purpose of manufacturing a high-quality color proof and by this system, a halftone image of 150 lines/inch or more is generally reproduced. For recording a high-quality proof from digital signals, laser light capable of modulating by the digital signals and sharply focusing the recording light is used as the recording head. Accordingly, the image-forming material used with the laser is required to exhibit high recording sensitivity to the laser light and high resolution for enabling the reproduction of high-definition halftone dots.

With respect to the image-forming material for use in the transfer image formation method using laser light, a heat-fusion transfer sheet is known, where a light-to-heat conversion layer capable of generating heat upon absorption of the laser light and an image-forming layer containing a pigment dispersed in a heat-fusible component such as wax or binder are provided on a support in this order (see, JP-A-5-58045 (the term “JP-A” as used herein means an “unexamined published Japanese patent application”)). According to the image formation method using this image-forming material, heat is generated on the light-to-heat conversion layer in the region irradiated with the laser light and the image-forming layer corresponding to the region is fused by the heat and transferred to an image-receiving sheet stacked and disposed on the transfer sheet, whereby a transfer image is formed on the image-receiving sheet.

JP-A-6-219052 discloses a thermal transfer sheet where a light-to-heat conversion layer containing a light-to-heat converting substance, a very thin (0.03 to 0.3 μm) thermal peeling layer and an image-forming layer containing a coloring material are disposed on a support in this order. In this thermal transfer sheet, the bonding strength between the image-forming layer and the light-to-heat conversion layer bonded with an intervention of the thermal peeling layer is diminished upon irradiation with laser light and a high-definition image is formed on an image-receiving sheet stacked and disposed on the thermal transfer sheet. This image formation method using the above-described thermal transfer sheet utilizes so-called “ablation”, more specifically, a phenomenon such that a part of the thermal peeling layer in the region irradiated with the laser light is decomposed and vaporized and thereby the bonding strength between the image-forming layer and the light-to-heat conversion layer is diminished in that region, as a result, the image-forming layer in this region is transferred to an image-receiving sheet stacked on the thermal transfer sheet.

These image formation methods are advantageous in that a printing paper having provided thereon an image-receiving layer (adhesive layer) can be used as the image-receiving sheet material and a multicolor image can be easily obtained by sequentially transferring images of different colors to the image-receiving sheet. In particular, the image formation method using ablation is advantageous in that a high-definition image can be easily obtained, therefore, this method is useful for the manufacture of a color proof (DDCP (direct digital color proof)) or a high-definition mask image.

With the progress of DTP environment, the intermediate step of outputting an image on a film is dispensed with and at the site of using a CTP (computer-to-plate) system, demands are increasing for changeover from the proof by printing or an analogue system to the proof by DDCP system. In recent years, a large-size DDCP having higher quality, higher stability and excellent printing agreement is demanded.

The laser thermal transfer system can print an image with high resolution and conventionally known systems include (1) a laser sublimation system, (2) a laser ablation system and a laser fusion system, but these systems all have a problem in that the recorded halftone dot fails in having a sharp shape. More specifically, the laser sublimation system (1) has a problem in that the approximation to the printed matter is not sufficiently high due to use of a dye as the coloring material and since a system of allowing the coloring material to sublimate is employed, the contour of a halftone dot is blurred and this gives rise to insufficient resolution. The laser ablation system (2) can attain good approximation to the printed matter but has a problem in that since a system of allowing the coloring material to splash is employed, the contour of a halftone dot is blurred similarly to the sublimation system and this gives rise to insufficient resolution. The laser fusion system (3) has a problem in that since the fused material flows, a clear contour cannot be attained.

In recording an image with laser light, laser light comprising multiple beams using a plurality of laser beams is recently used so as to shorten the recording time. However, if this recording with multibeam laser light is performed using a conventional thermal transfer sheet, the transfer of the transfer image formed on the image-receiving layer onto a printing paper sheet is accompanied with problems, for example, the transferability of fine lines is poor, the image transferred is readily scratched due to insufficient scratch resistance, or the transfer image sometimes floats. Furthermore, the printing paper used here is exclusive-use paper and normal copying paper or rough paper cannot be used.

### SUMMARY OF THE INVENTION

The present invention has been made to solve these problems in conventional techniques and the object of the present invention is to provide a large-size DDCP having high quality, high stability and excellent printing agreement.

More specifically, an object of the present invention is to provide a multicolor image-forming material which can satisfy the requirements: (1) that the thermal transfer sheet can be free of any effect from the illumination light source even in comparison with a pigment coloring material or with a printed matter and can give a halftone dot having good sharpness and excellent stability upon transfer of the coloring material thin film; (2) that the image-receiving sheet can stably and surely receive the image-forming layer of the laser energy thermal transfer sheet; (3) that the image can be transferred onto printing paper such as art (coat) paper, matted paper or finely coated paper in correspondence at least with the range of 64 to 157 g/m² and drawing with subtle massive feeling or exact paper white (highkey part) can be reproduced; and (4) that transfer peelability can be very stably obtained.

Another object of the present invention is to provide a multicolor image-forming material which can form an image having good image quality and stale transfer density on an image-forming sheet even when the laser recording is preformed with high energy using multibeam laser light under different temperature and humidity conditions.

Still another object of the present invention is to provide a multicolor image-forming material in which even when the laser recording is performed with high energy using multibeam laser light, the image-receiving sheet can ensure good transferability of fine lines at the time of transferring a transfer image formed on the image-receiving sheet onto paper, give a transferred image improved in the scratch resistance and image floating (separation between the printing paper and the transfer image) and allow use of normal rough paper as the transfer paper.

The means for attaining these objects of the present invention are as follows.

(1) A multicolor image-forming material of recording an image using an image-receiving sheet comprising a support having thereon at least an image-receiving layer, and thermal transfer sheets for forming four or more different colors each comprising a support having thereon at least a light-to-heat conversion layer and an image-forming layer, the image being recorded by superposing each the thermal transfer sheet and the image-receiving sheet such that the image-forming layer of the thermal transfer sheet and the image-receiving layer of the image-receiving sheet come to face each other, irradiating laser light and transferring the image-forming layer in the region irradiated with the laser light onto the image-receiving layer of the image-receiving sheet, wherein the adhesive tape peeling strength on the image-receiving layer surface of the image-receiving sheet is from 800 to 20,000 mN/cm at room temperature.

(2) The multicolor image-forming material as described in (1), wherein the adhesive tape peeling strength on the image-receiving layer surface of the image-receiving sheet is from 1,100 to 20,000 mN/cm at room temperature.

(3) The multicolor image-forming material as described in (1) or (2), wherein the contact angle to water of the image-receiving layer of the image-receiving sheet is from 10.0° to 120.0°.

(4) The multicolor image-forming material as described in any one of (1) to (3), wherein the contact angle to water of the image-receiving layer of the image-receiving sheet is from 30.0° to 120.0°.

(5) The multicolor image-forming material as described in any one of (1) to (4), wherein the contact angle to water of the image-forming layer of the image-receiving sheet is from 30.0° to 85.0°.

(6) The multicolor image-forming material as described in (1), wherein the adhesive tape peeling strength on the image-receiving layer surface of the image-receiving sheet is from 820 to 2,300 mN/cm at room temperature and the center line average surface roughness (Ra) on the image-receiving layer surface of the image-receiving sheet is from 0.01 to 0.3 μm.

(7) The multicolor image-forming material as described in (6), wherein the center line average surface roughness (Ra) on the image-receiving layer surface of the image-receiving sheet is from 0.02 to 0.25 μm.

(8) The multicolor image-forming material as described in (1) or (6), wherein the residual solvent amount in the image-receiving sheet as a whole is from 5 to 100 μl/m².

(9) The multicolor image-forming material as described in (8), wherein the residual solvent amount in the image-receiving sheet as a whole is from 20 to 60 μl/m².

(10) The multicolor image-forming material as described in (8), wherein the image-receiving layer of the image-receiving sheet contains a polymer or a composition thereof having a glass transition temperature (Tg) of 6 to 57° C. under humidity conditioning to 50% RH at 25° C.

(11) The multicolor image-forming material as described in any one of (1) to (10), wherein the image-receiving layer of the image-receiving sheet contains a polymer or a composition thereof having an elongation at break of 1 to 130% at 25° C. and 50% RH.

(12) The multicolor image-forming material as described in any one of (1) to (11), wherein the transfer image is an image having a resolution of 2,400 dpi or more.

(13) The multicolor image-forming material as described in any one of (1) to (12), wherein the transfer image is an image having a resolution of 2,600 dpi or more.

(14) The multicolor image-forming material as described in any one of (1) to (13), wherein the area of the multicolor image recorded is in a size of 515 mm or more×728 mm or more.

(15) The multicolor image-forming material as described in any one of (1) to (14), wherein the area of the multicolor image recorded is in a size of 594 mm or more×841 mm or more.

(16) The multicolor image-forming material as described in any one of (1) to (15), wherein the ratio (OD_{I}/layer thickness (unit: μm)) between the optical density (OD_{I}) and the layer thickness of the image-forming layer of each thermal transfer sheet is 1.50 or more.

(17) The multicolor image-forming material as described in any one of (1) to (16), wherein the ratio (OD_{I}/layer thickness (unit: μm)) between the optical density (OD_{I}) and the layer thickness of the image-forming layer of each thermal transfer sheet is 1.80 or more.

(18) The multicolor image-forming material as described in any one of (1) to (17), wherein the contact angle to water of the image-forming layer of each thermal transfer sheet is from 7.0 to 120.0°.

(19) The multicolor image-forming material as described in any one of (1) to (18), wherein the ratio (OD_{I}/layer thickness (unit: μm)) between the optical density (OD_{I}) and the layer thickness of the image-forming layer of each thermal transfer sheet is 1.80 or more and the contact angle to water of the image-receiving sheet is 85° or less.

(20) The multicolor image-forming material as described in any one of (1) to (19), wherein the ratio (OD_{I}/layer thickness (unit: μm)) between the optical density (OD_{I}) and the layer thickness of the image-forming layer of each thermal transfer sheet is 2.50 or more.

As a result of extensive investigations to provide a large-size DDCP of B2/A2 or more, or even B1/A1 or more, having high quality, high stability and excellent printing agreement, the present inventors have developed a laser thermal transfer recording system for DDCP, comprising an image-forming material of B2 size or more and of the transfer to printing paper/output of halftone dots/pigment type, an output machine and a high-grade CMS soft.

The characteristic features in performance, the system structure and the technical points of the laser thermal transfer recording system developed by the present inventors are briefly described below. (1) The dot shape is sharp and therefore, halftone dots with excellent approximation to a printed matter can be reproduced; (2) the color hue has good approximation to a printed matter; and (3) the recording quality is not easily affected by the ambient temperature and humidity and good repeated reproduction property is ensured, so that a proof can be stably prepared. The technical points in obtaining a material having such characteristic features of performance are the establishment of a thin-film transfer technique and the improvement in the vacuum intimate contact-holding property, the high-resolution recording follow-up property and the heat resistance of the material required on use in the laser thermal transfer system. More specifically, the technical points are (1) to form the light-to-heat conversion layer as a thin film by introducing an infrared absorbing dye; (2) to intensify the heat resistance of the light-to-heat conversion layer by introducing a high Tg polymer; (3) to stabilize the color hue by introducing a heat-resistant pigment; (4) to control the adhesive strength/cohesive strength by adding a low molecular component such as wax and inorganic pigment; and (5) to impart vacuum intimate adhesion property without deteriorating the image quality, by adding a matting agent to the light-to-heat conversion layer. The technical points for the system are, for example, (1) air transportation for the recording device so as to continuously accumulate a large number of sheets; (2) insertion of printing paper for the thermal transfer device so as to reduce curling after the transfer; and (3) connection of a general-use output driver having system-connecting and extending capability. The laser thermal transfer recording system developed by the present inventors is constructed by these various characteristic features of performance, the system structure and the technical points. However, these are only exemplary means and the present invention is not limited thereto.

The present inventors have made the development based on the thinking that individual materials, respective coated layers such as light-to-heat conversion layer, thermal transfer layer and image-receiving layer, respective thermal transfer sheets and the image-receiving sheet are not present independently from each other but must function organically and generically and the image-forming material constructed by these members can maximally exert its function when combined with a recording device or a thermal transfer device. The present inventors have made thorough examination on respective coated layers of the image-forming material and the constituent materials therefor, as a result, appropriate ranges of various physical properties have been found, where the characteristic features of those constituent materials for the coated layers can be maximally brought out and when an image-forming material is constructed, the image-forming material can maximally exert its performance. By intensely studying on the relationship among the materials, coated layers, sheets and physical properties from these results and furthermore, by combining the image-forming material with a recording device or a thermal transfer device to organically and generically function, a high-performance image-forming material has been unexpectedly found out. As for the positioning of the present invention in the system developed by the present inventors, firstly, the improvement of the image-receiving sheet is a point, namely, the present invention provides an image-receiving sheet which can attain good fixing of fine lines when the transfer image formed on the image-receiving sheet is transferred to paper. Secondly, in view of supporting the system developed by the present invention, a large picture plane is an important point of the high-performance image-forming material of the present invention. Furthermore, the embodiment of the present invention specifying the residual solvent amount in the image-receiving sheet as a whole is an important invention having great effect on the layer separation or the easiness of peeling.

### BRIEF DESCRIPTION OF THE DRAWINGS

FIG. 1 is a view for roughly explaining the mechanism of forming a multicolor image by the thermal transfer of a thin film using a laser.

FIG. 2 is a view showing a construction example of the recording device for laser thermal transfer.

FIG. 3 is a view showing a construction example of the thermal transfer device.

FIG. 4 is a view showing a construction example of the system using recording device FINALPROOF for laser thermal transfer.

The symbols in the above figures are explained below.

1 RECORDING DEVICE

2 RECORDING HEAD

3 SUB-SCANNING RAIL

4 RECORDING DRUM

5 THERMAL TRANSFER SHEET LOADING UNIT

6 IMAGE-RECEIVING SHEET ROLL

7 TRANSPORTATION ROLL

8 SQUEEZE ROLLER

9 CUTTER

10 THERMAL TRANSFER SHEET

10K, 10C, 10M, 10Y THERMAL TRANSFER SHEET ROLL

12 SUPPORT

14 LIGHT-TO-HEAT CONVERSION LAYER

16 IMAGE-FORMING LAYER

20 IMAGE-RECEIVING SHEET

22 SUPPORT FOR IMAGE-RECEIVING SHEET

24 IMAGE-RECEIVING LAYER

30 LAMINATE

31 DISCHARGE TABLE

32 DISCARD PORT

33 DISCHARGE PORT

34 AIR

35 DISCARD BOX

42 PRINTING PAPER

43 HEAT ROLLER

44 INSERTION TABLE

45 MARKS SHOWING POSITION WHERE SHEET IS PLACED

46 INSERTION ROLLER

47 GUIDE FORMED OF HEAT-RESISTANT SHEET

48 PEELING CLAW

49 GUIDE PLATE

50 DISCHARGE PORT

### DETAILED DESCRIPTION OF THE INVENTION

In the multicolor image-forming material of the present invention, the image-receiving layer as a constituent layer of the image-receiving sheet has an adhesive tape peeling strength of 800 mN/cm or more at room temperature.

In the present invention, the adhesive tape peeling strength is determined as follows. A 1 cm-width and 20 cm-length polyester adhesive tape (NITTO TAPE, produced by Nitto Electric Industrial Co., Ltd.) is fixed on the surface of a 2 cm-width and 8 cm-length image-receiving layer using a laminator at room temperature and the value when the tape is peeled off by TENSIRON (manufactured by Orientec) at an angle of 180° between the tape and the image-receiving layer surface under the conditions of a pulling rate of 50 mm/min. The room temperature as used herein means 25° C.

In the present invention, the peeling strength is preferably from 1,100 to 20,000 mN/cm. If the peeling strength is less than 800 mN/cm, the fixing of fine lines is not improved.

This peeling strength can be obtained by selecting the polymer or a composition thereof and additives such as antistatic agent and surfactant, used in the image-receiving layer.

The polymer for use in the image-receiving layer is preferably a thermoplastic resin and examples thereof include homopolymers and copolymers of acrylic monomers such as acrylic acid, methacrylic acid, acrylic acid ester and methacrylic acid ester; cellulose-based polymers such as methyl cellulose, ethyl cellulose and cellulose acetate; homopolymers and copolymers of vinyl-based monomers, such as polystyrene, polyvinyl pyrrolidone, polyvinyl butyral, polyvinyl alcohol and polyvinyl chloride; condensed polymers such as polyester and polyamide; and rubber-based polymers such as butadiene-styrene copolymer. This polymer or a composition thereof is appropriately selected from these compounds by taking account of the molecular weight, the monomer composition for the copolymer, or the polymer composition ratio for the composition. Among these, polyvinyl butyral (e.g., Eslec B BL-SH, produced by Sekisui Chemical Co., Ltd.) is preferred.

The additives such as antistatic agent are preferably added in an amount smaller than usual, for example, from 0 to 10 mass % (i.e., weight %) based on the polymer composition.

In the present invention, the transfer image can be improved in the fixing of fine lines and the scratch resistance by controlling the peeling strength.

The contact angle to water of the image-receiving layer for use in the present invention is preferably from 10.0 to 120.0°, more preferably from 30.0 to 120.0°, still more preferably from 30.0 to 85.0°.

In the present invention, the contact angle to water of the image-receiving layer is a value measured using a contact angle meter, Model CA-A (manufactured by Kyowa Kaimen Kagaku K.K.).

In one embodiment of the multicolor image-forming material of the present invention, the adhesive tape peeling strength on the image-receiving layer surface of the image-receiving sheet is controlled to 820 to 2,300 mN/cm and at the same time, the center line average surface roughness (Ra) on the image-receiving layer surface is controlled to 0.01 to 0.3 μm.

The adhesive tape peeling strength in this embodiment means a value determined as above.

With small Ra and smooth image-layer surface, the peeling strength is elevated and high resolution is results. If Ra is large and the image-receiving layer surface is rough, the peeling strength becomes low and the resolution decreases.

In the present invention, Ra is a value measured according to JIS B0601 using a surface roughness meter (Surfcom 570A-3DF, manufactured by Tokyo Seimitsu Co., Ltd.) or the like.

This peeling strength in the above-described range can be obtained by selecting the polymer or a composition thereof and additives such as antistatic agent and surfactant, used in the image-receiving layer.

As for the polymer used in the image-receiving layer, also in this embodiment, various compounds described above as the polymer or a composition thereof for use in the image-receiving layer can be appropriately selected and used.

The additives such as antistatic agent are preferably used in an amount smaller than usual, for example, from 0 to 10 mass % based on the polymer composition.

In this embodiment of the present invention, the transfer image can be more improved in the fixing of fine lines and the scratch resistance by controlling the peeling strength.

In still another embodiment of the multicolor image-forming material of the present invention, the residual solvent (e.g., methanol, n-propyl alcohol, toluene) in the image-receiving sheet as a whole is controlled to 5 to 100 μl/m². In view of attaining high sensitivity and good transferability to printing paper at the same time, it is very important to control the residual solvent in the image-receiving sheet as a whole to 5 to 100 μl/m². More specifically, if the residual solvent amount is less than 5 μl/m², the thermal transfer sensitivity decreases and thinning of fine lines or halftone dots and recording failure occur, whereas if the residual solvent amount exceeds 100 μl/m², a great peeling force is necessary in the transfer to printing paper and not only the operation becomes difficult but also paper tearing is sometimes generated to give a fatal defect. This defect is fatal particularly in uses such as proof, where a large-size image must be formed. For attaining high thermal transfer sensitivity and good printing paper transferability at the same time, the residual solvent amount is preferably adjusted to from 5 to 100 μl/m², more preferably from 5 to 80 μl/m², still more preferably from 20 to 60 μl/m².

The residual solvent amount is measured as follows. A sample of 0.0125 m² is sealed into a vial bottle and using a head spacer HSS-2A and a gas chromatograph GC-9A (manufactured by Shimadzu Corporation), the residual solvent is extracted under heating at 250° C. for 30 minutes and quantitated. For the sake of simplicity and easiness, the residual solvent amount is calculated in terms of MEK as follows:

Residual solvent amount (μL/m²) in terms of MEK=(0.1×b/a)/c

wherein

A: detection strength (area) of 10 μl of an 1% aqueous MEK solution (containing 0.1 μL of MEK) for measuring,

B: total detection strength (area) in the measurement of sample,

C: area (m²) of sample.

In still another embodiment of the multicolor image-forming material of the present invention, the image-receiving layer of the image-receiving sheet is formed using a polymer or a composition thereof having a glass transition temperature (Tg) of 6 to 57° C., preferably from 44 to 56° C., under humidity conditioning to 50% RH at 25° C., or using a polymer or a composition thereof having an elongation at break of 1 to 130%, preferably from 2 to 30%.

The Tg used here is a value measured by a method in which a polymer or a composition thereof subjected to humidity conditioning at 50% RH, 25° C. for one night or more is filled into a sealed cell made of stainless steel in an amount of about 10 mg, and the obtained sample is measured by using the differential thermal analysis (DSC) meter (“DSC 2920”, manufactured by TA Instrument Corp.), under the condition of a temperature-rising rate of 10° C./min.

The above elongation at break used here is a value determined by a value determined on a sample at 25° C. and 50% RH using TENSIRON (RTM-50, manufactured by Orientec) at a pulling rate of 50 mm/min. The sample is prepared by coating a polymer or a composition thereof dissolved in a solvent on a support such as PET to form a film having a thickness of 10 to 40 μm and cutting the film into strips of 5×70 mm.

The polymer for use in the formation of the image-receiving layer may be appropriately selected, also in this embodiment, from various compounds described above as the polymer or a composition thereof for use in the image-receiving layer. Furthermore, by selecting the molecular weight thereof, the monomer composition for the copolymer, or the polymer component ratio for the composition, the Tg can be controlled.

In this embodiment of the present invention, the above-described polymer is used in the image-receiving layer, whereby the transferability on the printing paper is enhanced, the transfer image is improved in the fixing of fine lines, the scratch resistance and the floating of image, and rough paper can be used as the printing paper. There is also an effect of lowering the transfer temperature of thermal transfer devices conventionally used for the transfer of an image on the printing paper.

The rough paper as used herein means non-coated paper having a rough surface (for example, copying paper). Examples of the rough paper include those having a center line average surface roughness Ra (measured according to JIS B0601 using a surface roughness meter (Surfcom, manufactured by Tokyo Seimitsu Co., Ltd.), etc.) of 3.1 μm and a surface roughness Rz of 24 μm.

In the multicolor image-forming material of the present invention including respective embodiments described above, the ratio (OD_{I}/layer thickness (unit: μm)) between the optical density (OD_{I}) and the layer thickness of the image-forming layer of each thermal transfer sheet is preferably 1.50 or more, more preferably 1.80 or more, still preferably 2.50 or more. The upper limit of the ratio OD_{I}/layer thickness is not particularly limited but at the present time, the upper limit is about 6 in view of the balance with other characteristics. The ratio OD_{I}/layer thickness is an index for the transfer density of the image-forming layer and for the transfer image. By setting the ratio OD_{I}/layer thickness to fall within the above-described range, the obtained image can have high transfer density and good resolution.

OD_{I} means a reflection optical density obtained when an image transferred from the thermal transfer sheet to the image-receiving sheet is further transferred to TOKUHISHI art paper as the printing paper and measured in respective color modes of yellow (Y), magenta (M), cyan (C) and black (K) using a densitometer (X-rite 938, manufactured by X-rite). OD_{I} is preferably from 0.5 to 4, more preferably from 1 to 2.

In the multicolor image-forming material of the present invention, the contact angle to water of the image-forming layer of each thermal transfer sheet is preferably from 7.0 to 120.0°. The contact angle is an index relating to the compatibility between the image-forming layer and the image-receiving layer, namely, the transferability. The contact angle of the image-forming layer is more preferably from 30.0 to 100.0°. The contact angle to water of the image-receiving layer is as described above). The contact angle falling within the above-described range is advantageous in that the transfer sensitivity can be elevated and the dependency of recording characteristics on temperature and humidity can be reduced.

In the present invention, the contact angle to water on the surface of each layer is a value determined, as described above, using a contact angle meter Model CA-A (manufactured by Kyowa Kaimen Kagaku K.K.).

In the multicolor image-forming material of the present invention, the multicolor image can be formed in a large picture plane. More specifically, the area of the multicolor image recorded can be made to a size of 515 mm or more×728 mm or more, even a size of 594 mm or more×841 mm or more.

In the present invention, the size of each thermal transfer sheet is preferably 20 to 80 mm larger than the size of the image-receiving sheet. If the difference in size is less than 20 mm, an appropriate vacuum adhesion state cannot be maintained and therefore, the degree of vacuum lowers, as a result, the transferability with the image-forming layer is liable to change for the worse. If the difference in size exceeds 80 mm, an air stays between the recording drum and the transfer sheet, as a result, there is a tendency that a vacuum adhesion state in good balance is not obtained.

The size of the printing paper is preferably 5 to 100 mm larger than the image-receiving sheet for use in the present invention. If the difference in size between the printing paper and the image-receiving sheet is less than this range, generation of wrinkles is liable to occur due to dislocation between samples from each other, whereas if the difference in size is excessively large, this is disadvantageous in view of cost.

The system as a whole developed by the present inventors including the contents of the present invention is described below. In the system of the present invention, a thin film thermal transfer system is created and employed, whereby high resolution and high image quality are attained. The system of the present invention is a system where a transfer image having a resolution of 2,400 dpi or more, preferably 2,600 dpi or more, can be obtained. The thin film thermal transfer system is a system where an image-forming layer thin film having a layer thickness of 0.01 to 0.9 μm and being in a partially or mostly non-fused state is transferred to an image-receiving sheet. That is, in the thermal transfer system developed, the recorded area is transferred as a thin film and therefore, extremely high resolution is attained. For performing the thin film thermal transfer with good efficiency, the inside of the light-to-heat conversion layer is preferably deformed into a dome shape by photorecording, so that the image-forming layer can be lifted to intensify the adhesive strength between the image-forming layer and the image-receiving layer and thereby facilitate the transfer. When the deformation is large, the force of pressing the image-forming layer to the image-receiving layer becomes large and the transfer is facilitated. If the deformation is small, the force of pressing the image-forming layer to the image-receiving layer is small and the transfer may not be successfully attained in some portions. The deformation size preferred for the thin film transfer can be evaluated by the deformation percentage which is calculated, on the observation through a laser microscope (VK8500, manufactured by KIENCE), by adding the increased sectional area (a) of the recording part of the light-to-heat conversion layer after the photorecording and the sectional area (b) of the recording part of the light-to-heat conversion layer before the photorecording, dividing the obtained value by the sectional area (b) of the recording part of the light-to-heat conversion layer before the photorecording, and multiplying this obtained value by 100. That is, the deformation percentage={(a+b)/(b)}×100. The deformation percentage is 110% or more, preferably 125% or more, more preferably 150% or more. If the elongation at break is set to large, the deformation percentage may exceed 250%, however, it is usually preferred to suppress the deformation percentage to about 250% or less.

The technical points of the image-forming material for use in the thin film transfer are as follows.

1. Compatibility of High Heat Responsibility and Storability

For achieving high image quality, a thin film in the submicron order must be transferred, however, a layer having dispersed therein a pigment in a high concentration must be formed so as to obtain a desired density. This contradicts to the heat responsibility. The heat responsibility is also in the contradicting relation with the storability (adhesion). These contradicting relations are overcome by the development of novel polymer and additives.

2. Securance of High Vacuum Adhesion

For the thin film transfer seeking for high resolution, the transfer interface is preferably smooth, however, if the case is so, sufficiently high vacuum adhesion cannot be obtained. Unboud from conventional common sense in regard to the technique of imparting vacuum adhesion property, a matting agent having a relatively small particle size is added in a slightly larger amount to the layer under the image-forming layer, whereby an appropriate gap is uniformly kept between the thermal transfer sheet and the image-receiving sheet, the image is prevented from sliding due to the matting agent and while ensuring the characteristic features of the thin film transfer, vacuum adhesion property is imparted.

3. Use of Heat-Resistant Organic Material

At the laser recording, the light-to-heat conversion layer of converting the laser light to heat reaches about 700° C. and the image-forming layer containing a pigment coloring material reaches about 500° C. A modified polyimide capable coating with an organic solvent has been developed as the material for the light-to-heat conversion layer and at the same time, a pigment having heat resistance higher than that of pigments for printing and being safe and agreed in the color hue has been developed as the pigment coloring material.

4. Securance of Surface Cleanness

In the thin film transfer, a dust between the thermal transfer sheet and the image-receiving sheet works out to an image defect and raises a serious problem. The dust invades from the outside of instrument or is generated at the cutting of a material and therefore, cannot be sufficiently prevented only by the control of materials and a mechanism for removing dusts must be provided to the instrument. However, a material capable of cleaning the transfer material surface and maintaining an appropriate tackiness has been found and the removal of dust has been realized without changing the construction material of transportation roller and thereby decreasing the productivity.

The system of the present invention is described in detail below.

The present invention is a system where a thermal transfer image formed of sharp halftone dots is realized, transfer to the printing paper and, as described above, recording of B2 size or more (515 mm or more×728 mm or more) can be performed and furthermore, recording even in a size of 594 mm or more×841 mm or more can be attained.

A first characteristic feature in performance of the system developed by the present invention is in that a sharp dot shape can be obtained. The thermal transfer image obtained by this system can be a halftone image according to the printing screen ruling with a resolution of 2,400 dpi or more. Individual dots are almost free of blurring or missing and favored with a very sharp shape and therefore, halftone dots over a wide range from highlight to shadow can be clearly formed. As a result, high-level halftone dots can be output with the same resolution as in the image setter or CTP setter and the reproduced halftone dot and gradation can have good approximation to the printed matter.

A second characteristic feature in performance of the system developed by the present invention is in that the repeated reproduction property is good. This thermal transfer image is favored with a sharp dot shape and therefore, halftone dots responding to a laser beam can be faithfully reproduced. Also, since the dependency of recording characteristics on the ambient temperature and humidity is very small, the color hue and the density both can be stably and repeatedly reproduced in an environment over a wide range of temperature and humidity.

A third characteristic feature of the system developed by the present invention is in that the color reproduction is good. The thermal transfer image obtained by this system is formed using a colored pigment for use in printing ink and also favored with good repeated reproduction property, so that high-precision CMS (color management system) can be realized.

Furthermore, this thermal transfer image can be almost completely agreed with the color hue such as Japan color or SWOP color, namely, the color hue of printed matter, and the change in the viewing of colors accompanying the change of light source such as fluorescent lamp or incandescent lamp can be the same as on the printed matter.

A fourth characteristic feature in performance of the system developed by the present invention is in that the letter image quality is good. The thermal transfer image obtained by this system is favored with a sharp dot shape and therefore, fine lines of a fine letter can be sharply reproduced.

The characteristics of the material technique for the system of the present invention are described in more detail below. The thermal transfer system for DDCP includes (1) a sublimation system, (2) an ablation system and (3) a heat fusion system. In the systems (1) and (2), the coloring material is sublimated or splashed and therefore, the contour of a halftone dot is blurred. In the system (3), the fused matter flows and therefore, a clear contour cannot be obtained. The present inventors have introduced the following techniques based on the thin film transfer technique so as to solve the problems newly caused in the laser thermal transfer system and attain higher image quality.

The first characteristic feature of the material technique is in that the dot shape is sharpened. The recording of an image is performed by converting laser light into heat in the light-to-heat conversion layer and transmitting the heat to the adjacent image-forming layer to allow the image-forming layer to adhere to the image-receiving layer. The heat generated by the laser light does not diffuse in the plane direction but is transmitted to the transfer interface, as a result, the image-forming layer is sharply broken at the interface between the heated part and the non-heated part, whereby the dot shape can be sharpened. For this purpose, the thermal transfer sheet is controlled in the thinning of the light-to-heat conversion layer and in the dynamic characteristics of the image-forming layer.

The technique 1 for the sharpening of the dot shape is the thinning of the light-to-heat conversion layer. In a simulation, the light-to-heat conversion layer is presumed to momentarily reach about 700° C. and if the film is thin, the layer is readily deformed or broken. If the deformation or breakage occurs, there arise troubles, more specifically, the light-to-heat conversion layer is transferred to the image-receiving sheet together with the image-forming layer or a non-uniform transfer image is formed. On the other hand, for obtaining a predetermined temperature, a light-to-heat conversion substance must be present in the film at a high concentration and this causes a problem, for example, the dye may precipitate or migrate to the adjacent layer. Conventionally, carbon is used as the light-to-heat conversion substance in many cases, however, in the material of the present invention, an infrared absorbing dye which can work with a small amount as compared with carbon is used. As for the binder, a polyimide-based compound ensuring a sufficiently high dynamic strength even at high temperatures and having high capability of holding the infrared absorbing dye is introduced.

As such, by selecting an infrared absorbing dye having excellent light-to-heat conversion property and a heat-resistant binder such as polyimide-base compound, the light-to-heat conversion layer is preferably reduced in the thickness to about 0.5 μm or less.

The technique 2 for sharpening the dot shape is the improvement in properties of the image-forming layer. If the light-to-heat conversion is deformed or the image-forming layer itself is deformed due to heat at a high temperature, the image-forming layer transferred to the image-receiving layer causes unevenness in the thickness correspondingly to the sub-scanning pattern of the laser light, as a result, the image becomes non-uniform and the apparent transfer density decreases. This tendency is more serious as the thickness of the image-forming layer is smaller. On the other hand, if the thickness of the image-forming layer is large, the sharpness of a dot is impaired and at the same time, the sensitivity decreases.

In order to attain these contradictory performances at the same time, a low melting point substance such as wax is preferably added to the image-forming layer to improve the transfer unevenness. Also, inorganic fine particles may be added in place of a binder to properly increase the layer thickness and thereby allow the image-forming layer to sharply break at the interface between the heated part and the unheated part, so that the transfer unevenness can be improved while maintaining the sharpness of a dot and the sensitivity.

Generally, the low melting point substance such as wax has a tendency to bleed out to the surface of the image-forming layer or undertake crystallization and in some cases, this substance causes a problem in the image quality or the aging stability of the thermal transfer sheet.

For solving this problem, a low melting point substance having a small difference in the SP value from the polymer of the image-forming layer is preferably used, whereby the compatibility with the polymer can be elevated and the separation of the low melting point substance from the image-forming layer can be prevented. Also, several kinds of low melting point substances different in the structure are preferably mixed to provide an eutectic state and thereby prevent the crystallization. By employing this means, an image having a sharp dot shape and reduced in the unevenness can be obtained.

The second characteristic feature of the material technique is in the finding that the recording sensitivity has dependency on temperature and humidity. In general, when the coated layer of the thermal transfer sheet absorbs moisture, the layer is changed in the dynamic properties and thermal properties to generate temperature and humidity dependency of the recording environment.

In order to reduce this temperature and humidity dependency, the dye/binder system of the light-to-heat conversion layer and the binder system of the image-forming layer each is preferably an organic solvent system. In addition, while selecting a polyvinyl butyral as the binder of the image-receiving layer, a polymer hydrophobitization technique is preferably introduced so as to reduce the water absorptivity of the binder. Examples of the polymer hydrophobitization technique include a technique of reacting a hydroxyl group with a hydrophobic group described in JP-A-8-238858 and a technique of crosslinking two or more hydroxyl groups by a hardening agent.

The third characteristic feature of the material technique is in that the approximation to a printed matter is improved. In addition to the color matching and stable dispersion technique of a pigment in a color proof (for example, First Proof produced by Fuji Photo Film Co., Ltd.) prepared using a thermal head system, the following problems newly generated in the laser thermal transfer system are solved. That is, the technique 1 in the improvement of approximation of the color hue to a printed matter is the use of a highly heat-resistant pigment. Usually, a heat of about 500° C. or more is applied to the image-forming layer at the time of printing an image by a laser exposure and some pigments conventionally used are thermally decomposed but this can be prevented by employing a highly heat-resistant pigment for the image-forming layer.

The technique 2 in the improvement of approximation of the color hue to a printed matter is to prevent the diffusion of infrared absorbing dye. Due to heat of high temperature at the printing of an image, the infrared absorbing dye migrates from the light-to-heat conversion layer into the image-forming layer and the color hue is changed. For preventing this, as described above, the light-to-heat conversion layer is preferably designed using a combination of an infrared absorbing dye having high holding power with a binder.

The fourth characteristic feature of the material technique is in the elevation of sensitivity. In general, high-speed printing of an image causes shortage of energy and generates gaps particularly corresponding to the intervals of the laser sub-scanning. As described above, the elevation of the dye concentration in the light-to-heat conversion layer and the reduction in the thickness of the light-to-heat conversion layer/image-forming layer can increase the efficiency in generation/transmission of heat. Furthermore, for the purpose of providing an effect of allowing the image-forming layer to slightly fluidize at the heating and thereby fill the gap and also elevating the adhesive property to the image-forming layer, a low melting point substance is preferably added to the image-forming layer. In addition, for elevating the adhesive property between the image-receiving layer and the image-forming layer and ensuring a sufficiently high strength for the image transferred, the same polyvinyl butyral as, for example, in the image-forming layer is preferably employed as the binder of the image-receiving layer.

The fifth characteristic feature of the material technique is in the improvement of vacuum adhesion property. The image-receiving sheet and the thermal transfer sheet are preferably held on a drum by vacuum adhesion. This vacuum adhesion is important because the image is formed by controlling the adhesive strength between those two sheets and the image transfer behavior is very sensitive to the clearance on the image-receiving layer surface of the image-receiving sheet and the image-forming layer surface of the transfer sheet. If a foreign matter such as dust triggers widening of the clearance between materials, image defect or uneven image transfer is caused.

For preventing such image defect or uneven image transfer, uniform asperities are preferably provided on the thermal transfer sheet so as to attain good passing of air and obtain uniform clearance.

The technique 1 in the improvement of vacuum adhesion property is the formation of asperities on the surface of the thermal transfer sheet. The asperities are provided on the thermal transfer sheet so that the vacuum adhesion effect can be satisfactorily brought out even in the case of printing an image by superposing two or more colors. For providing asperities on the thermal transfer sheet, after-treatment (such as embossing) or addition of a matting agent to the coated layer is generally employed, however, for simplifying the production process and stabilizing the material in aging, the addition of a matting agent is preferred. The matting agent must have a larger size than the thickness of the coated layer. If the matting agent is added to the image-forming layer, the image in the area of allowing the presence of the matting agent is missed. Therefore, a matting agent having an optimal particle size is preferably added to the light-to-heat conversion layer. By adding as such, the image-forming layer itself can have almost a uniform thickness and an image free of defects can be obtained on the image-receiving sheet.

The characteristic features of the systematization technique for the system of the present invention are described below. The first characteristic feature of the systematization technique is in the construction of the recording device. In order to realizing the above-described sharp dot without fail, a high-precision design is demanded also in the recording device side. The fundamental construction is the same as conventional recording devices for laser thermal transfer. The construction is a so-called heat mode outer drum recording system where a recording head equipped with a plurality of high-power lasers irradiates the lasers on a thermal transfer sheet and an image-receiving sheet, which are fixed on a drum. Among these constructions, the following embodiment is preferred.

The construction 1 of the recording device is to avoid the intermingling of a dust. The image-receiving sheet and the thermal transfer sheet are fed by full automatic roll feeding. The feeding of a small number of sheets often allows the intermingling of a dust generated from the human body and therefore, the roll feeding is employed.

Four colors have respective rolls of thermal transfer sheet and therefore, these rolls are switched over by the rotation of a loading unit. Each film is cut into a predetermined length by a cutter during the loading and then fixed to a drum.

The construction 2 of the recording device is to intensify the adhesion between the image-receiving layer and the thermal transfer sheet on the recording drum. The image-receiving layer and the thermal transfer sheet each is fixed to the recording drum by vacuum adsorption. If these sheets are fixed by mechanical means, the adhesive strength between the image-receiving layer and the thermal transfer sheet cannot be intensified and therefore, the vacuum adsorption is employed. On the recording drum, a large number of vacuum adsorption holes are formed and the pressure inside the drum is reduced using a blower or a decompression pump, whereby the sheet is adsorbed to the drum. Through the image-receiving sheet in the adsorbed state, the thermal transfer sheet is further adsorbed and therefore, the size of the thermal transfer sheet is rendered larger than the image-receiving sheet. The air between the thermal transfer sheet and the image-receiving layer, which has a greatest effect on the recording performance, is suctioned from the area only of the thermal transfer sheet out of the image-receiving sheet.

The construction 3 of the recording device is to stably accumulate a plurality of sheets on the discharge table. In the present device, many large-area sheets of B2 size or more can be accumulated one on another in the discharge table. If next sheet B is discharged on the image-receiving layer having thermal adhesive property of the already accumulated film A, these sheets may be stuck each other and if stuck, next sheet cannot be correctly discharged and jamming is disadvantageously caused. The most effective means for preventing the sticking is to prevent films A and B from contacting. For preventing this contact, several methods are known. That is, (a) a method of providing a portion difference in the height to the discharge table to render the film shape non-flat and thereby form a space between the films; (b) a method of providing a discharge port at the position higher than the discharge table and falling the film to be discharged from a height; and (c) a method of blowing an air between two sheets and floating the film which is discharged later. In the system of the present invention, the sheet size is very large of B2 and if the methods (a) and (b) are employed, a very large structure is necessary. Therefore, the air blowing method (c) is employed, that is, a method of blowing an air between two sheets and floating the sheet which is discharged later is employed.

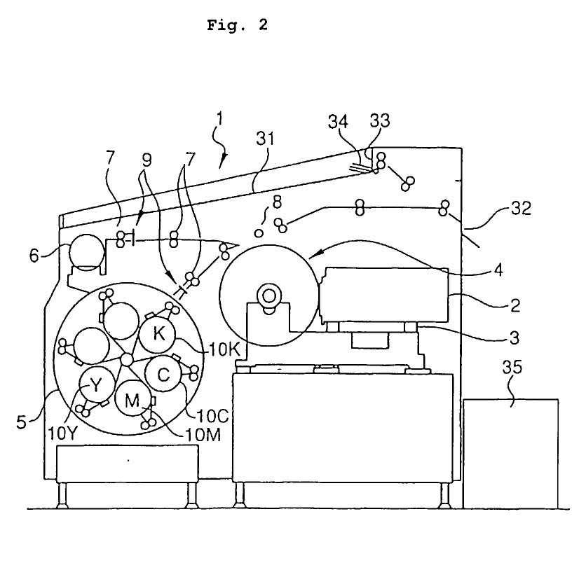

FIG. 2 shows a construction example of this device.

The sequence of forming a full color image by applying the image-forming material to this device (hereinafter referred to an “image-forming sequence of this system”) is described below.

1) In a recording device 1, the sub-scan axis of the recording head 2 is returned to the original point by means of a subs-scan rail 3, and also the main scan rotation axis of the recording drum 4 and the thermal transfer sheet loading unit 5 are returned to respective original points.

2) An image-receiving sheet roll 6 is untied by a transportation roller 7 and the leading end of the image-receiving sheet is vacuum-suctioned through suction holes provided on a recording drum 4 and fixed on the recording drum.

3) A squeeze roller 8 comes down on the recording drum 4 to press the image-receiving sheet and stops pressing when a predetermined amount of the image-receiving sheet is transported by the rotation of the drum, and the image-receiving sheet is cut by a cutter 9 to a predetermined length.

4) The recording drum continues to make one rotation and thereby, the loading of the image-receiving sheet is completed.

5) In the same sequence as that for the image-receiving sheet, a thermal transfer sheet K having a first color (black) is drawn out from a thermal transfer sheet roll 10K and cut to complete the loading.

6) Then, the recording drum 4 starts rotating at a high speed, the recording head 2 on the sub-scan rail 3 starts moving and when the recording head reached a recording initiation position, a recording laser is irradiated on the recording drum 4 by the recording head 2 according to the recording image signals. The irradiation is finished at the recording completion position and the moving of sub-scan rail and the rotation of drum are stopped. The recording head on the sub-scan rail is returned to the original point.

7) While allowing the image-receiving sheet to remain on the recording drum, only the thermal transfer sheet K is peeled off. The leading end of the thermal transfer sheet K was hooked by a nail, pulled out in the discharge direction and discarded to the discard box 35 through the discard port 32.

8) 5) to 7) are repeated for transferring remaining three color portions. The recording order subsequent to black is cyan, magenta and yellow in this order. More specifically, a thermal transfer sheet C having a second color (cyan), a thermal transfer sheet M having a third color (magenta) and a thermal transfer sheet Y having a fourth color (yellow) are sequentially drawn out from a thermal transfer sheet roll 10C, a thermal transfer sheet roll 10M and a thermal transfer sheet roll 10Y, respectively. The transfer order is generally reversed to the printing order and this is because at the transfer on the printing paper in the later step, the color order on the printing paper is reversed.

9) After the completion of transfer of four colors, the recorded image-receiving sheet is finally discharged to a discharge table 31. The image-receiving sheet is peeled off from the drum in the same manner as that for the thermal transfer sheet in 7), however, unlike the thermal transfer sheet, the image-receiving sheet is not discarded and therefore, when transported until the discard port 32, is returned to the discharge table by means of switch back. On discharging the image-receiving sheet into the discharge table, an air 34 is blown from the lower part of the discharge port 33, so that a plurality of sheets can be accumulated.

An adhesive roller having provided on the surface thereof an adhesive material is preferably used for any one transportation roller 7 disposed at the positions of feeding or transporting the thermal transfer sheet roll or the image-receiving sheet roll.

By providing an adhesive roller, the surfaces of the thermal transfer sheet and the image-receiving sheet can be cleaned.

Examples of the adhesive material provided on the surface of the adhesive roller include an ethylene-vinyl acetate copolymer, an ethylene-ethyl acrylate copolymer, a polyolefin resin, a polybutadiene resin, a styrene-butadiene copolymer (SBR), a styrene-ethylene-butene-styrene copolymer (SEBS), an acrylonitrile-butadiene copolymer (NBR), a polyisoprene resin (IR), a styrene-isoprene copolymer (SIS), an acrylic acid ester copolymer, a polyester resin, a polyurethane resin, an acrylic resin, a butyl rubber and polynorbornene.

The adhesive roller is put into contact with the surface of the thermal transfer sheet or the image-receiving sheet, whereby the surface of the thermal transfer sheet or the image-receiving sheet can be cleaned.

The material having tackiness for use on the adhesive roller preferably has a Vickers hardness Hv of 50 kg/mm² (≈490 MPa) or less because dusts as a foreign matter can be satisfactorily removed and the image defect can be prevented.

The Vickers hardness is a hardness when a static load is imposed on a regular quadrangular pyramid-shaped diamond indentator having a diagonal angle of 136° and the hardness is measured. The Vickers hardness Hv can be determined by the following formula:

Hardness Hv=1.854 P/d²(kg/mm²)≈18.1692 P/d²(MPa)

wherein

P: the size of load (kg),

d: the length of a diagonal line of the square recession.

The symbol “≈” means “=about”, that is, means “is (are) approximately equal”.

In the present invention, the material having tackiness for use on the adhesive roller preferably has an elastic modulus of 200 kg/cm² (≈19.6 MPa) or less because, similarly to the above, dusts as a foreign matter can be satisfactorily removed and the image defect can be prevented.

The second characteristic feature of the systematization technique is in the construction of the thermal transfer device.

For performing the step of transferring the image-transfer sheet having printed thereon an image by a recording device to the paper for printing (hereinafter referred to as “printing paper”), a thermal transfer device is used. This step is completely the same as in the First Proof™. When the image-receiving sheet and a printing paper are superposed and heat and pressure are applied thereon, two paper sheets are bonded and on peeling off the image-receiving film from the printing paper, only the image and the adhesive layer remain on the printing paper but the image-receiving sheet support and the cushion layer are peeled off. Accordingly, in practice, the image is transferred from the image-receiving sheet to the printing paper.

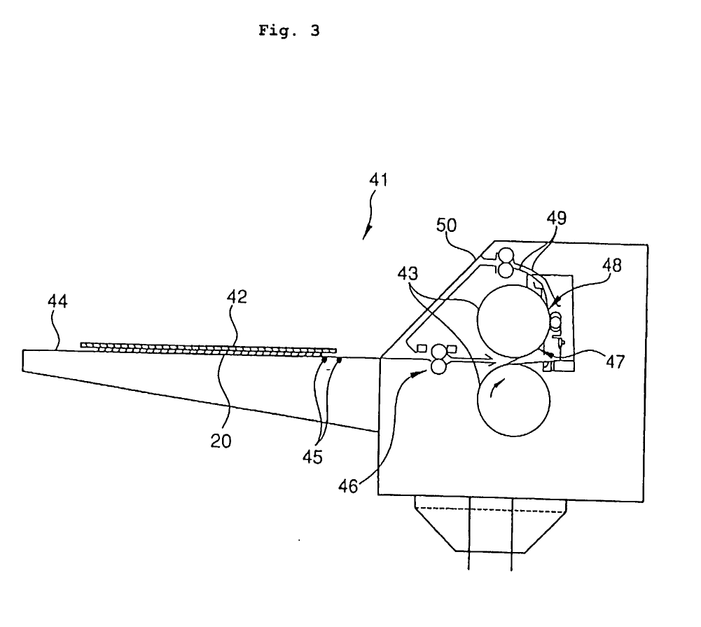

In First Proof™, a printing paper and an image-receiving sheet are superposed, placed on an aluminum-made guide plate and passed through heat rollers, whereby transferring the image. The aluminum guide plate is used so as to prevent the deformation of printing plate. However, if this plate is used for the B2 size system of the present invention, an aluminum guide plate larger than B2 is necessary and the space for the installation of the device is disadvantageously enlarged. Therefore, in the system of the present invention, an aluminum guide plate is not used and a structure such that the transportation path is rotated at 180° to discharge the sheets toward the insertion side is employed, so that the installation space can be very compact (see, FIG. 3). However, since the aluminum guide plate is not used, deformation of the printing plate is disadvantageously generated. More specifically, a pair of printing paper and image-receiving sheet discharged are inwardly curled and roll down on the discharge table. The peeling off of the image-receiving sheet from the rolled printing paper is a very difficult operation.

Accordingly, a method of preventing the rolling is studied and there are thought out a bimetal effect using the difference in the shrinkage amount between the printing paper and the image-receiving sheet and an iron effect by a structure of taking the sheets around a heat roll. In the case of inserting these sheets while superposing the image-receiving sheet on a printing paper as in conventional techniques, since the heat shrinkage of the image-receiving sheet in the direction of the insertion proceeding is larger than the heat shrinkage of the printing paper, the upper side of curling by the bimetal effect is the inward side and this is the same as the direction of the iron effect, as a result, the curling becomes severer due to their synergistic effect. However, when the image-receiving sheet is inserted to come under the printing paper, the curling by the bimetal effect is directed downward but the curling by the iron effect is directed upward, so that the curling is canceled and causes no problem.

The sequence of the transfer to the printing paper is described below (hereinafter referred to as “printing paper transfer method for use in the system of the present invention”). FIG. 3 shows a thermal transfer device 41 for use in this method, which is a device by the manual operation unlike the recording device.

1) According to the kind of the printing paper 42, the temperature of the heat roller 43 (100 to 110° C.) and the transportation speed at the transfer are set using a dial (not shown).

2) An image-receiving sheet 20 is place on the insertion table by facing the image upward and dusts on the image are removed by an electrification-removing brush (not shown). Thereon, a printing paper 42 after removal of dusts is superposed. At this time, the printing paper 42 superposed on the image-receiving film placed lower has a larger size and therefore, the position of the image-receiving sheet 20 cannot be seen to make the positioning difficult. In order to improve this problem in the operation, marks 45 are made on the insertion table 44 to show the positions for placing the image-receiving sheet and the printing paper, respectively. The printing paper has a larger size so as to prevent the image-receiving sheet 20 from sliding and protruding from the printing paper 42 and the image-receiving layer of the image-receiving sheet 20 from contaminating the heat roller 43.

3) The image-receiving sheet and the printing paper are pressed into the insertion port while superposing one on another and thereupon, the insertion rollers 46 rotate to deliver two sheets toward heat rollers 43.

4) When the leading end of the printing paper reaches the position of heat rollers 43, the heat rollers are nipped and the transfer starts. The heat rollers are a heat-resistant silicon rubber roller. In this place, pressure and heat are simultaneously applied, whereby the image-receiving sheet is adhered to the printing paper. Downstream the heat rollers, a guide 47 made of a heat-resistant sheet is disposed and the pair of image-receiving sheet and printing paper are transported between the upstream heat roller and the guide 47 while being applied with heat, peeled off from the heat roller at the position of peeling claw 48, and guided along the guide plate 49 to the discharge port 50.

5) The pair of image-receiving sheet and printing paper coming out from the discharge port 50 are discharged on the insertion table while these sheets remaining in a adhered state. Afterward, the image-receiving sheet 20 is manually peeled off from the printing paper 42.

The third characteristic feature of the systematization technique is in the construction of the system.

The above-described devices are connected on a plate-making system and thereby allowed to exert the function as a color proof. The system is required to output, from the proof, a print having an image quality as close as that of a printed matter output based on certain plate-making data and for realizing this, a software for approximating colors and halftone dots to those of a printed matter is necessary. The connection example is specifically described below.

In the case of preparing a proof of a printed matter from a plate-making system Celebra™ manufactured by Fuji Photo Film Co., Ltd., the system is connected as follows. A CTP (computer-to-plate) system is connected to Celebra. A printing plate output therefrom is mounted on a press and a final printed matter is obtained. The Celebra is connected with a color proof Luxel FINALPROOF 5600 (hereinafter sometimes referred to as “FINALPROOF”) manufactured by Fuji Photo Film Co., Ltd. which is the above-described recording device, but PD System™ manufactured by Fuji Photo Film Co., Ltd. is connected therebetween as a proof drive software for approximating colors and halftone dots to those of a printed matter.

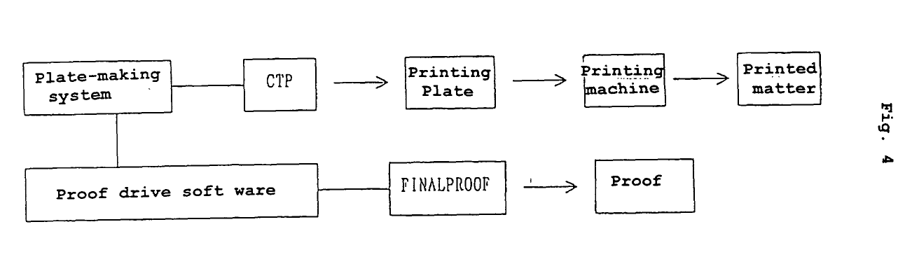

The CONTONE (continuous tone) data converted into raster data in Celebra are converted into binary data for halftone dots, output to the CTP system and finally printed. On the other hand, the same CONTONE data are output also to the PD system. The PD system converts the received data using a four-dimensional (black, cyan, magenta and yellow) table to give colors agreeing with those of the printed matter and finally converts the data into binary data for halftone dots to give halftone dots agreeing with those of the printed matter. These data are output to FINALPROOF (see, FIG. 4).

The four-dimensional table is previously prepared by performing an experiment and stored in the system. The experiment for the preparation of data is performed as follows. After preparing an image printed through a CTP system from important color data and an image output to the FINALPROOF through the PD system and comparing the measured color values, a table is prepared such that the difference in the measured color values is minimized.

As described above, a system construction capable of fully exerting the capacity of a material having high resolution can be realized in the present invention.

The thermal transfer sheet as a material for use in the system of the present invention is described below.

The absolute value of the difference between the surface roughness Rz on the image-forming layer surface of the thermal transfer sheet and the surface roughness Rz on the surface of the backside layer thereof is preferably 3.0 μm or less and the absolute value of the difference between the surface roughness Rz on the image-receiving layer surface of the image-receiving sheet and the surface roughness Rz on the surface of the backside layer thereof is preferably 3.0 μm or less. By virtue of this construction in combination with the above-described cleaning means, the image defects can be prevented, the jamming of sheets on transportation can be prohibited and the dot gain stability can be improved.

The surface roughness Rz as used in the present invention means a ten point average surface roughness corresponding to Rz (maximum height) defined by JIS and this is determined as follows. A basic area portion is extracted from the roughness curved surface and using an average face in this portion as the basic face, the distance between the average altitude of projections from the highest to the fifth height and the average depth of troughs from the deepest to the fifth depth is input and converted. For the measurement, a probe-system three-dimensional roughness meter (Surfcom 570A-3DF) manufactured by Tokyo Seimitsu Co., Ltd. is used. The measured direction is longitudinal direction, the cut-off value is 0.08 mm, the measured area is 0.6 mm×0.4 mm, the feed pitch is 0.005 mm and the measurement speed is 0.12 mm/s.

From the standpoint of more improving the above-described effect, the absolute value of difference between the surface roughness Rz on the image-forming layer surface of the thermal transfer sheet and the surface roughness Rz on the surface of the backside layer thereof is preferably 1.0 μm or less and the absolute value of difference between the surface roughness Rz on the image-receiving layer surface of the image-receiving sheet and the surface roughness Rz on the surface of the backside layer thereof is preferably 1.0 μm or less.

In another embodiment, the image-forming layer surface of the thermal transfer sheet and the surface of the backside layer thereof and/or the front and back surfaces of the image-receiving sheet preferably have a surface roughness Rz of 2 to 30 μm. By having such a construction in combination with the above-described cleaning means, the image defects can be prevented, the jamming of sheets on transportation can be prohibited and the dot gain stability can be improved.

The glossiness on the image-forming layer of the thermal transfer sheet is preferably from 80 to 99.

The glossiness greatly depends on the smoothness on the surface of the image-forming layer and affects the uniformity in the layer thickness of the image-forming layer. With a high glossiness, the image-forming layer can be uniform and more suitable for uses of forming a highly precise image, however, if the smoothness is higher, the resistance at the transportation becomes larger. Thus, the glossiness and the smoothness are in the trade-off relationship but these can be balanced when the glossiness is from 80 to 99.

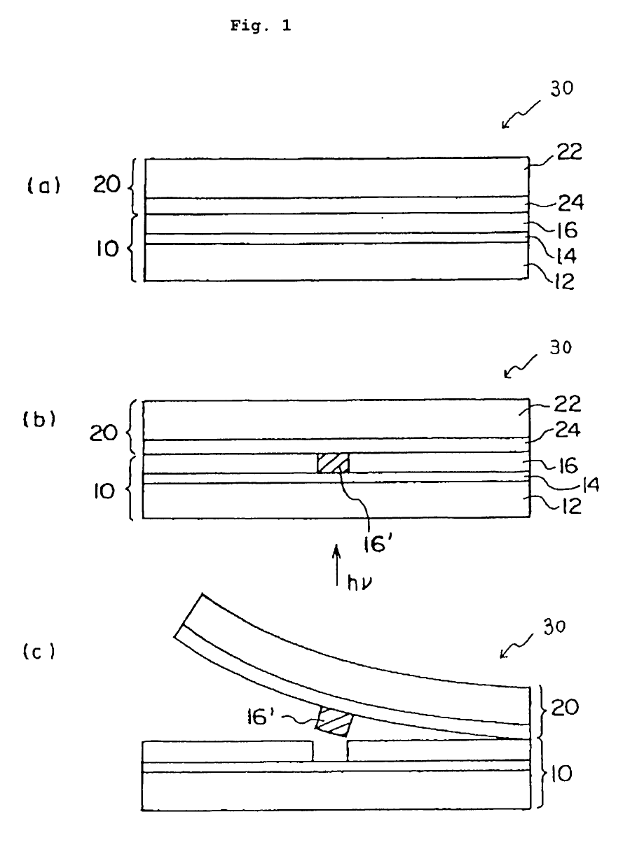

The mechanism of forming a multicolor image by the thermal transfer of a thin film using a laser is roughly described below by referring to FIG. 1.

On the image-forming layer 16 containing a pigment of black (K), cyan (C), magenta (M) or yellow (Y) of the thermal transfer sheet 10, an image-receiving sheet 20 is stacked to prepare an image-forming laminate 30. The thermal transfer sheet 10 comprises a support 12 having thereon a light-to-heat converting layer and further thereon an image-forming layer 16, and the image-receiving sheet 20 comprises a support 22 having thereon an image-receiving layer 24 and is stacked such that the image-receiving layer 24 comes into contact with the surface of the image-forming layer 16 of the thermal transfer sheet 10 (see, FIG. 1(a)). When laser light is imagewise irradiated in time series on the obtained laminate 30 from the support side of the thermal transfer sheet 10, the light-to-heat conversion layer 14 of the thermal transfer sheet 10 in the region irradiated with the laser light generates heat and decreases in the adhesive strength with the image-forming layer 16 (see, FIG. 1(b)). Thereafter, the image-receiving sheet 20 and the thermal transfer sheet 10 are peeled off, and then the region 16′ irradiated with the laser light in the image-forming layer 16 is transferred to the image-receiving layer 24 of the image-receiving sheet 20 (see FIG. 1(c)).

In the formation of a multicolor image, the laser light used for the light irradiation is preferably multibeam laser light, more preferably light of multibeam two-dimensional arrangement. The multibeam two-dimensional arrangement means that on performing the recording by laser irradiation, a plurality of laser beams are used and the spot arrangement of these laser beams forms a two-dimensional plane arrangement comprising a plurality of rows along the main scanning direction and a plurality of lines along the sub-scanning direction.

By using the laser light in multibeam two-dimensional arrangement, the time period necessary for the laser recording can be shortened.

Any laser light can be used without any limitation. For example, gas laser light such as argon ion laser light, helium-neon laser light and helium-cadmium laser light, solid-state laser light such as YAG laser light, or direct laser light such as semiconductor laser light, dye laser light and excimer laser light, is used. In addition, for example, light converted into a half wavelength by passing the above-described laser light through a secondary higher harmonic device may also be used. In the formation of a multicolor image, semiconductor laser light is preferred on considering the output power and the easiness in modulation. In the method for forming a multicolor image, the laser light is preferably irradiated under the conditions such that the beam diameter is from 5 to 50 μm (particularly from 6 to 30 μm) on the light-to-heat conversion layer. The scanning speed is preferably 1 m/sec or more (particularly 3 m/sec or more).

In the multicolor image formation, the thickness of the image-forming layer in the black thermal transfer sheet is preferably larger than that of the image-forming layer in each of yellow, magenta and cyan thermal transfer sheet and is preferably from 0.5 to 0.7 μm. By constructing as such, the reduction in density due to transfer unevenness can be suppressed at the laser irradiation of the black thermal transfer sheet.

By setting the layer thickness of the image-forming layer in the black thermal transfer sheet to 0.5 μm or more, the image density can be maintained without causing transfer unevenness on recording at a high energy and an image density necessary as a proof of printing can be achieved. This tendency is more outstanding under high humidity conditions and the change in density depending on the environment can be prevented. On the other hand, by setting the layer thickness to 0.7 μm or less, the transfer sensitivity can be maintained at the laser recording and fixing of small points or fine lines can also be improved. This tendency is more outstanding under low humidity conditions. Also, the resolution can be elevated. The layer thickness of the image-forming layer in the black thermal transfer sheet is more preferably from 0.55 to 0.65 μm, still more preferably 0.60 μm.

Furthermore, it is preferred that the layer thickness of the image-forming layer in the black thermal transfer sheet is from 0.5 to 0.7 μm and the layer thickness of the image-forming layer in each of the yellow, magenta and cyan thermal transfer sheets is from 0.2 μm to less than 0.5 μm.

By setting the layer thickness of the image-forming layer in each of the yellow, magenta and cyan thermal transfer sheets to 0.2 μm or more, the density can be maintained without causing transfer unevenness at the laser recording, also by setting the layer thickness to less than 0.5 μm, the transfer sensitivity or the resolution can be elevated. The layer thickness is more preferably from 0.3 to 0.45 μm.

The image-forming layer in the black thermal transfer sheet preferably contains carbon black. The carbon black preferably comprises at least two kinds of carbon blacks different in the coloring power because the reflection density can be adjusted while keeping a constant P/B (pigment/binder) ratio.

The coloring power of carbon black is expressed by various methods and, for example, PVC blackness described in JP-A-10-140033 may be used. The PVC blackness is determined as follows. Carbon black is added to PVC resin, dispersed by means of a twin roller and formed into a sheet and by setting the base values while taking the blackness of Carbon Black “#40” and “#45” produced by Mitsubishi Chemical as Point 1 and Point 10, respectively, the blackness of the sample is evaluated by the judgement with an eye. Two or more carbon blacks different in the PVC blackness can be appropriately selected and used according to the purpose.

The method for preparing a sample is specifically described below.

<Production Method of Sample>

In a 250 ml-volume Banbury mixer, 40 mass % (i.e., weight %) of a sample carbon black is blended with LDPE (low-density polyethylene) resin and kneaded at 115° C. for 4 minutes.

Blending Conditions:

| | |
|---|---|
| LDPE resin | 101.89 g |
| Calcium stearate | 1.39 g |
| Irganox 1010 | 0.87 g |
| Sample carbon black | 69.43 g |

Then, the kneaded material is diluted at 120° C. by a twin roller mill to a carbon black concentration of 1 mass %.

Conditions in Manufacture of Diluted Compound:

| | |
|---|---|
| LDPE resin | 58.3 g |
| Calcium stearate | 0.2 g |
| Resin having blended therein 40 mass % of | 1.5 g |
| carbon black | |

The diluted compound was processed into a sheet form through a 0.3 mm-width slit and the obtained sheet is cut into chips and formed into a film of 65±3 μm on a hot plate at 240° C.

With respect to the method for forming a multicolor image, a multicolor image may be formed using, as described above, the thermal transfer sheet and repeatedly superposing a large number of image layers (image-forming layers having formed thereof an image) on the same image-receiving sheet. Also, a multicolor image may be formed by once forming an image on each image-receiving layer of a plurality of image-receiving sheets and re-transferring the images to printing paper or the like.

In the latter case, for example, thermal transfer sheets having an image-forming layer containing a coloring material different in the color hue from each other are prepared and four kinds (four colors: cyan, magenta, yellow and black) of laminates for image formation are produced each by combining with an image-receiving sheet. On each laminate, for example, laser light is irradiated through a color separation filter according to digital signals based on an image and subsequently, the thermal transfer sheet is peeled off from the image-receiving sheet to independently form a color separation image of each color on each image-receiving sheet. Respective color separation images formed are sequentially stacked on a separately prepared actual support such as printing paper or on a support approximated thereto, whereby a multicolor image can be formed.

In the thermal transfer sheet using laser light irradiation, an image-forming layer containing a pigment is preferably transferred to an image-receiving sheet by making use of heat energy resulting from the conversion of laser beams into heat. These techniques used for the development of an image-forming material comprising a thermal transfer sheet and an image-receiving sheet can be appropriately applicable to the development of thermal transfer sheet and/or image-forming sheet using a system such as fusion transfer, ablation transfer or sublimation transfer. The system of the present invention includes the image-forming materials used in these systems.

The thermal transfer sheet and the image-receiving sheet are described in detail below.

[Thermal Transfer Sheet]

The thermal transfer sheet comprises a support having thereon at least a light-to-heat conversion layer and an image-forming layer and if desired, additionally having other layers.

(Support)

The material for the support of the thermal transfer sheet is not particularly limited and various support materials may be used according to the end use. The support preferably has rigidity, good dimensional stability and durability against heat on the image formation. Preferred examples of the support material include synthetic resin materials such as polyethylene terephthalate, polyethylene-2,6-naphthalate, polycarbonate, polymethyl methacrylate, polyethylene, polypropylene, polyvinyl chloride, polyvinylidene chloride, polystyrene, styrene-acrylonitrile copolymer, polyamide (aromatic or aliphatic), polyimide, polyamidoimide and polysulfone. Among these, biaxially stretched polyethylene terephthalate is preferred in view of the mechanical strength and dimensional stability against heat. In the case of use for the manufacture of a color proof using laser recording, the support of the thermal transfer sheet is preferably formed of a transparent synthetic resin material capable of transmitting laser light. The thickness of the support is preferably from 25 to 130 μm, more preferably from 50 to 120 μm. The center line average surface roughness Ra (measured according to JIS B0601 using a surface roughness meter (Surfcom, manufactured by Tokyo Seimitsu Co., Ltd.)) of the support in the image-forming layer side is preferably less than 0.1 μm. The Young's modulus in the longitudinal direction of the support is preferably from 200 to 1,200 kg/mm² (≈2 to 12 GPa) and the Young's modulus in the cross direction is preferably from 250 to 1,600 kg/mm² (≈2.5 to 16 GPa). The F-5 value in the longitudinal direction of the support is preferably from 5 to 50 kg/mm² (≈49 to 490 MPa) and the F-5 value in the cross direction of the support is preferably from 3 to 30 kg/mm² (≈29.4 to 294 MPa). The F-5 value in the longitudinal direction of the support is generally higher than the F-5 value in the cross direction of the support but this does not apply when the strength particularly in the cross direction must be rendered high. The heat shrinkage percentage at 100° C. for 30 minutes in the longitudinal and cross directions of the support is preferably 3% or less, more preferably 1.5% or less, and the heat shrinkage at 80° C. for 30 minutes is preferably 1% or less, more preferably 0.5% or less. The breaking strength is preferably from 5 to 100 kg/mm² (≈49 to 980 MPa) in both directions and the elastic modulus is preferably from 100 to 2,000 kg/mm² (≈0.98 to 19.6 GPa).

The support of the thermal transfer sheet may be subjected to a surface activation treatment and/or a treatment of providing one or more undercoat layer so as to improve the adhesive property to the light-to-heat conversion layer provided on the support. Examples of the surface activation treatment include a glow discharge treatment and a corona discharge treatment. The material for the undercoat layer preferably exhibits high adhesive property to the surface of both the support and the light-to-heat conversion layer and has small heat conductivity and excellent heat resistance. Examples of such a material for the undercoat layer include styrene, styrene-butadiene copolymers and gelatin. The thickness of the entire undercoat layer is usually from 0.01 to 2 μm. If desired, the surface of the thermal transfer sheet in the side opposite the side where the light-to-heat conversion layer is provided may be subjected to a treatment of providing various functional layers such as antireflection layer and antistatic layer, or to a surface treatment.

(Back Layer)

A back layer is preferably provided on the surface of the thermal transfer sheet of the present invention in the side opposite the side where the light-to-heat conversion layer is provided. The back layer is preferably constructed by two layers, namely, a first back layer adjacent to the support and a second back layer provided on the support in the side opposite the first back layer. In the present invention, the ratio B/A of the mass A (i.e., the weight A) of the antistatic agent contained in the first back layer to the mass B (i.e., the weight B) of the antistatic agent contained in the second back layer is preferably less than 0.3. If the B/A ratio is 0.3 or more, the sliding property and the powder-falling off from the back layer are liable to change for the worse.

The layer thickness C of the first back layer is preferably from 0.01 to 1 μm, more preferably from 0.01 to 0.2 μm. The layer thickness D of the second back layer is preferably from 0.01 to 1 μm, more preferably from 0.01 to 0.2 μm. The ratio C:D in the film thickness between these first and second back layers is preferably from 1:2 to 5:1.

Examples of the antistatic agent which can be used in the first and second back layers include nonionic surfactants such as polyoxyethylene alkylamine and glycerol fatty acid ester, cationic surfactants such as quaternary ammonium salt, anionic surfactants such as alkyl phosphate, amphoteric surfactants, and compounds such as electrically conducting resin.

An electrically conducting fine particle can also be used as the antistatic agent. Examples of the electrically conducting fine particle include oxides such as ZnO, TiO₂, SnO₂, Al₂O₃, In₂O₃, MgO, BaO, CoO, CuO, Cu₂O, CaO, SrO, BaO₂, PbO, PbO₂, MnO₃, MoO₃, SiO₂, ZrO₂, Ag₂O, Y₂O₃, Bi₂O₃, Ti₂O₃, Sb₂O₃, Sb₂O₅, K₂Ti₆O₁₃, NaCaP₂O₁₈ and MgB₂O₅; sulfides such as CuS and ZnS; carbides such as SiC, TiC, ZrC, VC, NbC, MoC and WC; nitrides such as Si₃N₄, TiN, ZrN, VN, NbN and Cr₂N; borides such as TiB₂, ZrB₂, NbB₂, TaB₂, CrB, MoB, WB and LaB₅; silicides such as TiSi₂, ZrSi₂, NbSi₂, TaSi₂, CrSi₂, MoSi₂ and WSi₂; metal salts such as BaCO₃, CaCO₃, SrCO₃, BaSO₄ and CaSO₄; and composite materials such as SiN₄—SiC and 9Al₂O₃—2B₂O₃. These particles may be used individually or in combination of two or more thereof. Among these, SnO₂, ZnO, Al₂O₃, TiO₂, In₂O₃, MgO, BaO and MoO₃ are preferred, SnO₂, ZnO, In₂O₃ and TiO₂ are more preferred, and SnO₂ is still more preferred.

In the case of using the thermal transfer material of the present invention in the laser thermal transfer system, the antistatic agent used in the back layer is preferably substantially transparent so that the laser light can transmit therethrough.

In the case of using an electrically conducting metal oxide as the antistatic agent, the particle size thereof is preferably smaller so as to reduce the light scattering as much as possible, however, the particle size must be determined using the ratio in the refractive index between the particle and the binder as a parameter and can be obtained using the Mie Scattering Theory. The average particle size is generally from 0.001 to 0.5 μm, preferably from 0.003 to 0.2 μm. The average particle size as used herein is a value including not only a primary particle size of the electrically conducting metal oxide but also a particle size of higher structures.

In addition to the antistatic agent, various additives such as surfactant, sliding agent and matting agent, or a binder may be added to the first and second back layers. The amount of the antistatic agent contained in the first back layer is preferably from 10 to 1,000 parts by mass, more preferably from 200 to 800 parts by mass, per 100 parts by mass (by weight) of the binder. The amount of the antistatic agent contained in the second back layer is preferably from 0 to 300 parts by mass, more preferably from 0 to 100 parts by mass, per 100 parts by mass of the binder.

Examples of the binder which can be used in the formation of first and second back layers include homopolymers and copolymers of acrylic acid-based monomers such as acrylic acid, methacrylic acid, acrylic acid ester and methacrylic acid ester; cellulose-based polymers such as nitrocellulose, methyl cellulose, ethyl cellulose and cellulose acetate; vinyl-based polymers and copolymers of vinyl compounds, such as polyethylene, polypropylene, polystyrene, vinyl chloride copolymer, vinyl chloride-vinyl acetate copolymer, polyvinyl pyrrolidone, polyvinyl butyral and polyvinyl alcohol; condensed polymers such as polyester, polyurethane and polyamide; rubber-based thermoplastic polymers such as butadiene-styrene copolymer; polymers resulting of polymerization or crosslinking of a photopolymerizable or thermopolymerizable compound such as epoxy compound; and melamine compounds.

(Light-to-Heat Conversion Layer)

The light-to-heat conversion layer contains a light-to-heat conversion substance, a binder and if desired, a matting agent. Furthermore, if desired, the light-to-heat conversion layer contains other components.

The light-to-heat conversion substance is a substance having a function of converting light energy on irradiation into heat energy. This substance is generally a dye (including a pigment, hereinafter the same) capable of absorbing laser light. In the case of performing the image recording using an infrared laser, an infrared absorbing dye is preferably used as the light-to-heat conversion substance. Example of the dye include black pigments such as carbon black; pigments formed of a macrocyclic compound having absorption in the region from visible to near infrared, such as phthalocyanine and naphthalocyanine; organic dyes used as a laser-absorbing material in the high-density laser recording of an optical disk or the like, such as cyanine dyes (e.g., indolenine dye), anthraquinone-based dyes, azulene-based dyes and phthalocyanine-based dyes; and organometallic compound dyes such as dithiol-nickel complex. Among these, cyanine-based dyes are preferred because this dye exhibits a high absorption coefficient to light in the infrared region and when used as a light-to-heat conversion substance, the thickness of the light-to-heat conversion layer can be reduced, as a result, the recording sensitivity of the thermal transfer sheet can be more improved.

Other than the dye, particulate metal materials such as blacked silver, and inorganic materials may also be used as the light-to-heat conversion substance.

The binder contained in the light-to-heat conversion layer is preferably a resin having at least a strength sufficiently large to form a layer on a support and having a high heat conductivity. A resin having heat resistance and being incapable of decomposing even by the heat generated from the light-to-heat conversion substance on image recording is more preferred because even when light irradiation of higher energy is performed, the smoothness on the surface of the light-to-heat conversion layer can be maintained after the light irradiation. More specifically, a resin having a thermal decomposition temperature (a temperature of giving decrement of 5 mass % according to the TGA method (thermogravimetric analysis) in an air stream at a temperature-rising rate of 10° C./min) of 400° C. or more is preferred and a resin having the thermal decomposition temperature of 500° C. or more is more preferred. Also, the binder preferably has a glass transition temperature of 200 to 400° C., more preferably from 250 to 350° C. If the glass transition temperature is less than 200° C., fogging may be generated on the formed image, whereas if it exceeds 400° C., the solubility of the resin decreases and the production efficiency may be lowered.

The heat resistance (for example, thermal deformation temperature or thermal decomposition temperature) of the binder in the light-to-heat conversion layer is preferably high as compared with the materials used in other layers provided on the light-to-heat conversion layer.

Specific examples of the binder include acrylic acid-based resin (e.g., polymethyl methacrylate) polycarbonate, polystyrenes, vinyl-based resins (e.g., vinyl chloride/vinyl acetate copolymer and polyvinyl alcohol), polyvinyl butyral, polyester, polyvinyl chloride, polyamide, polyimide, polyether imide, polysulfone, polyether sulfone, aramid, polyurethane, epoxy resin and urea/melamine resin. Among these, polyimide resin is preferred.

In particular, the polyimide resins represented by the following formulae (I) to (VII) are soluble in an organic solvent and such a polyimide resin is preferably used because the productivity of the thermal transfer sheet is improved. Use of these resins is preferred also in view of viscosity stability, long-term storability and humidity resistance of the coating solution for the light-to-heat conversion layer.

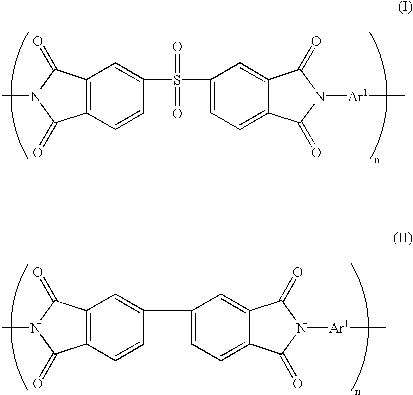

wherein Ar¹ represents an aromatic group represented by the following formula (1), (2) or (3), and n represents an integer of 10 to 100;

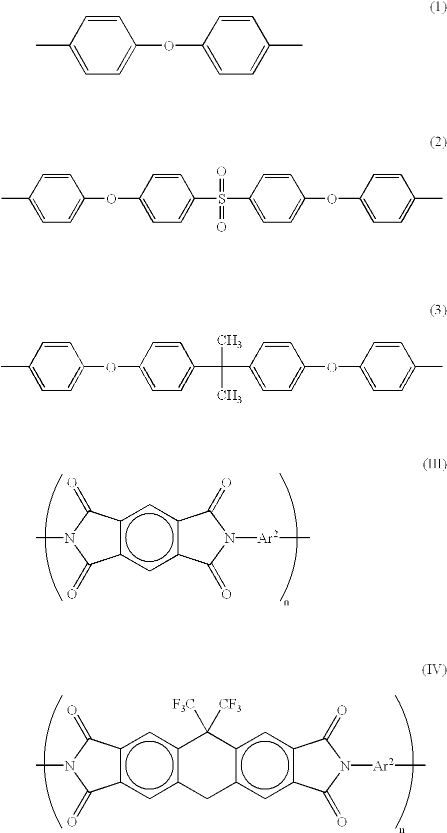

wherein Ar² represents an aromatic group represented by the following formula (4), (5), (6) or (7), and n represents an integer of 10 to 100;

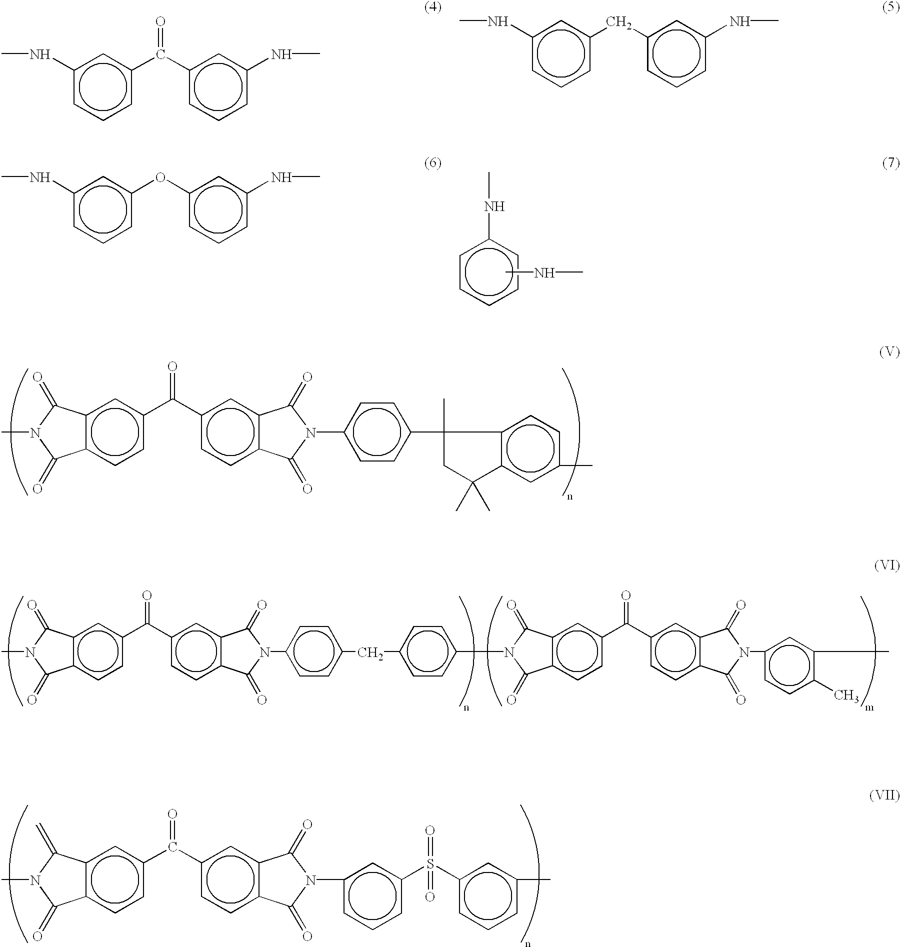

wherein in formulae (V) to (VII), n and m each represents an integer of 10 to 100, and in formula (VI), the ratio n:m is from 6:4 to 9:1.

As for the standard for the judgement whether or not the resin is soluble in an organic solvent, on the basis that 10 parts by mass (by weight) of resin is dissolved at 25° C. per 100 parts by mass of N-methylpyrrolidone, when 10 parts by mass of resin is dissolved, the resin is preferably used as the resin for the light-to-heat conversion layer. When 100 parts by mass of resin is dissolved per 100 parts by mass of N-methylpyrrolidone, this resin is more preferred.

Examples of the matting agent contained in the light-to-heat conversion layer include inorganic fine particle and organic fine particle. Examples of the inorganic fine particle include metal salts such as silica, titanium oxide, aluminum oxide, zinc oxide, magnesium oxide, barium sulfate, magnesium sulfate, aluminum hydroxide, magnesium hydroxide and boron nitride, kaolin, clay, talc, zinc white, white lead, zieklite, quartz, kieselguhr, pearlite, bentonite, mica and synthetic mica. Examples of the organic fine particle include fluororesin particle, guanamine resin particle, acrylic resin particle, styrene-acryl copolymer resin particle, silicone resin particle, melamine resin particle and epoxy resin particle.

The particle size of the matting agent is usually from 0.3 to 30 μm, preferably from 0.5 to 20 μm, and the amount of the matting agent added is preferably 0.1 to 100 mg/m².

The light-to-heat conversion layer may contain, if desired, a surfactant, a thickener, an antistatic agent and the like.

The light-to-heat conversion layer can be provided by preparing a coating solution having dissolved therein a light-to-heat conversion substance and a binder and if desired, having added thereto a matting agent and other components, applying the coating solution onto a support and drying the solution. Examples of the organic solvent for dissolving the polyimide resin include n-hexane, cyclohexane, diglyme, xylene, toluene, ethyl acetate, tetrahydrofuran, methyl ethyl ketone, acetone, cyclohexanone, 1,4-dioxane, 1,3-dioxane, dimethyl acetate, N-methyl-2-pyrrolidone, dimethylsulfoxide, dimethylformamide, dimethylacetamide, γ-butyrolactone, ethanol and methanol. The coating and drying may be performed using ordinary coating and drying methods. The drying is usually performed at a temperature of 300° C. or less, preferably at a temperature of 200° C. or less. In the case where polyethylene terephthalate is used as the support, the drying is preferably performed at a temperature of 80 to 150° C.

If the amount of the binder in the light-to-heat conversion layer is excessively small, the cohesion of the light-to-heat conversion layer decreases and at the time of transferring a formed image to an image-receiving sheet, the light-to-heat conversion layer is readily transferred together and this causes color mixing of the image, whereas if the polyimide resin is in an excessively large amount, the layer thickness of the light-to-heat conversion layer increases so as to achieve a constant light absorptivity and this readily incurs reduction in sensitivity. The mass ratio (i.e., weight ratio) of the solid contents between the light-to-heat conversion substance and the binder in the light-to-heat conversion layer is preferably from 1:20 to 2:1, more preferably from 1:10 to 2:1.

As described above, reduction in the thickness of the light-to-heat conversion is preferred because the sensitivity of the thermal transfer sheet can be elevated. The thickness of the light-to-heat conversion layer is preferably from 0.03 to 1.0 μm, more preferably from 0.05 to 0.5 μm. Furthermore, the light-to-heat conversion layer preferably has an optical density of 0.80 to 1.26, more preferably from 0.92 to 1.15, for the light at a wavelength of 808 nm, whereby the image-forming layer can be improved in the transfer sensitivity. If the optical density at a laser peak wavelength is less than 0.80, the irradiated light is insufficiently converted into heat and the transfer sensitivity lowers in some cases. On the other hand, if it exceeds 1.26, this affects the function of the light-to-heat conversion layer on recording and fogging may be generated. In the present invention, the optical density of the light-to-heat conversion layer in the thermal transfer sheet means absorptivity of the light-to-heat conversion layer at the peak wavelength of laser light used on performing the recording of the image-forming material of the present invention. The optical density can be measured using a known spectrophotometer. In the present invention, UV-spectrophotometer UV-240 manufactured by Shimadzu Corporation. The optical density is a value obtained by subtracting the value of the support alone from the value including the support.

(Image-Forming Layer)

The image-forming layer contains at least a pigment which is transferred to an image-receiving sheet and forms an image, and further contains a binder for forming the layer and if desired, other components.

The pigment in general is roughly classified into an organic pigment and an inorganic pigment. These are appropriately selected according to the use end by taking account of their properties, that is, the former provides a coating film having high transparency and the latter generally exhibits excellent masking property. In the case where the thermal transfer sheet is used for a color proof in printing, an organic pigment having a color tone agreeing with or close to yellow, magenta, cyan or black printing ink employed in general is used. Other than these, a metal powder, a fluorescent pigment or the like is used in some cases. Examples of the pigment which is preferably used include azo-type pigments, phthalocyanine-type pigments, anthraquinone-type pigments, dioxazine-type pigments, quinacridone-type pigments, isoindolinone-type pigments and nitro-type pigments. The pigments for use in the image-forming layers, classified by the color hue, are described below, however, the present invention is not limited thereto.

1) Yellow Pigment

Pigment Yellow 12 (C.I. No. 21090):

Permanent Yellow DHG (produced by Clariant Japan), Lionol Yellow 1212B (produced by Toyo Ink), Irgalite Yellow LCT (produced by Ciba Specialty Chemicals), Symuler Fast Yellow GTF 219 (produced by Dainippon Ink & Chemicals Inc.)

Pigment Yellow 13 (C.I. No. 21100):

Permanent Yellow GR (produced by Clariant Japan), Lionol Yellow 1313 (produced by Toyo Ink)

Pigment Yellow 14 (C.I. No. 21095):

Permanent Yellow G (produced by Clariant Japan), Lionol Yellow 1401-G (produced by Toyo Ink), Seika Fast Yellow 2270 (produced by Dainichi Seika Kogyo), Symuler Fast Yellow 4400 (produced by Dainippon Ink & Chemicals Inc.)

Pigment Yellow 17 (C.I. No. 21105):

Permanent Yellow GG02 (produced by Clariant Japan), Symuler Fast Yellow 8GF (produced by Dainippon Ink & Chemicals Inc.)

Pigment Yellow 155:

Graphtol Yellow 3GP (produced by Clariant Japan)

Pigment Yellow 180 (C.I. No. 21290):

Novoperm Yellow P-HG (produced by Clariant Japan, PV Fast Yellow HG (produced by Clariant Japan)

Pigment Yellow 139 (C.I. No. 56298):

Novoperm Yellow M2R 70 (produced by Clariant Japan)

2) Magenta Pigment

Pigment Red 57:1 (C.I. No. 15850:1):

Graphtol Rubine L6B (produced by Clariant Japan), Lionol Red 6B-4290G (produced by Toyo Ink), Irgalite Rubine 4BL (produced by Ciba Specialty Chemicals), Symuler Brilliant Carmine 6B-229 (produced by Dainippon Ink & Chemicals Inc.)

Pigment Red 122 (C.I. No. 73915):

Hosterperm Pink E (produced by Clariant Japan), Lionogen Magenta 5790 (produced by Toyo Ink), Fastogen Super Magenta RH (produced by Dainippon Ink & Chemicals Inc.)

Pigment Red 53:1 (C.I. No. 15585:1):

Permanent Lake Red LCY (produced by Clariant Japan), Symuler Lake Red C conc (produced by Dainippon Ink & Chemicals Inc.)

Pigment Red 48:1 (C.I. No. 15865:1):

Lionol Red 2B 3300 (produced by Toyo Ink), Symuler Red NRY (produced by Dainippon Ink & Chemicals Inc.)

Pigment Red 48:2 (C.I. No. 15865:2):

Permanent Red W2T (produced by Clariant Japan), Lionol Red LX235 (produced by Toyo Ink), Symuler Red 3012 (produced by Dainippon Ink & Chemicals Inc.)

Pigment Red 48:3 (C.I. No. 15865:3):

Permanent Red 3RL (produced by Clariant Japan), Symuler Red 2BS (produced by Dainippon Ink & Chemicals Inc.)

Pigment Red 177 (C.I. No. 65300):

Cromophtal Red A2B (produced by Ciba Specialty Chemicals)

3) Cyan Pigment:

Pigment Blue 15 (C.I. No. 74160):

Lionol Blue 7027 (produced by Toyo Ink), Fastogen Blue BB (produced by Dainippon Ink & Chemicals Inc.)

Pigment Blue 15:1 (C.I. No. 74160):

Hosterperm Blue A2R (produced by Clariant Japan), Fastgen Blue 5050 (produced by Dainippon Ink & Chemicals Inc.)

Pigment Blue 15:2 (C.I. No. 74160):

Hosterperm Blue AFL (produced by Clariant Japan), Irgalite Blue BSP (produced by Ciba Specialty Chemicals), Fastgen Blue GP (produced by Dainippon Ink & Chemicals Inc.)

Pigment Blue 15:3 (C.I. No. 74160):

Hosterperm Blue B2G (produced by Clariant Japan), Lionol Blue FG7330 (produced by Toyo Ink), Cromophtal Blue 4GNP (produced by Ciba Specialty Chemicals), Fastgen Blue FGF (produced by Dainippon Ink & Chemicals Inc.)

Pigment Blue 15:4 (C.I. No. 74160):

Hosterperm Blue BFL (produced by Clariant Japan), Cyanine Blue 700-10FG (produced by Toyo Ink), Irgalite Blue GLNF (produced by Ciba Specialty Chemicals), Fastgen Blue FGS (produced by Dainippon Ink & Chemicals Inc.)Pigment Blue 15:6 (C.I. No. 74160):

Lionol Blue ES (produced by Toyo Ink)

Pigment Blue 60 (C.I. No. 69800):

Hosterperm Blue RL01 (produced by Clariant Japan), Lionogen Blue 6501 (produced by Toyo Ink)

4) Black Pigment

Pigment Black 7 (Carbon Black C.I. No. 77266):

Mitsubishi Carbon Black MA100 (produced by Mitsubishi Chemical), Mitsubishi Carbon Black #5 (produced by Mitsubishi Chemical), Black Pearls 430 (produced by Cabot Co.)

The pigment which can be used in the present invention can be appropriately selected from commercially available products by referring to, for example, Ganryo Binran (Handbook of Pigments), compiled by Nippon Ganryo Gijutsu Kyokai, Seibundo Shinkosha (1989), and Color Index, The Society of Dyes & Colorist, 3rd ed.

The average particle size of the pigment is preferably from 0.03 to 1 μm, more preferably from 0.05 to 0.5 μm.

When the particle size is 0.03 μm or more, increase in the dispersion cost or gelling of the dispersion solution is not generated, whereas when the particle size is 1 μm or less, coarse pigment particles are absent in the pigment, therefore, good adhesion can be attained between the image-forming layer and the image-receiving layer and the image-forming layer can also be improved in the transparency.

The binder for the image-forming layer is preferably an amorphous organic high molecular polymer having a softening point of 40 to 150° C. Examples of the amorphous organic high molecular polymer include butyral resin, polyamide resin, polyethyleneimine resin, sulfonamide resin, polyester polyol resin, petroleum resin, homopolymers and copolymers of styrene or a derivative or substitution product thereof (e.g., styrene, vinyl toluene, α-methylstyrene, 2-methylstyrene, chlorostyrene, vinylbenzoic acid, sodium vinylbenzenesulfonate, aminostyrene), and homopolymers and copolymers with another monomer of a vinyl-based monomer such as methacrylic acid esters (e.g., methyl methacrylate, ethyl methacrylate, butyl methacrylate, hydroxyethyl methacrylate), methacrylic acid, acrylic acid esters (e.g., methyl acrylate, ethyl acrylate, butyl acrylate, α-ethylhexyl acrylate), acrylic acid, dienes (e.g., butadiene, isoprene) , acrylonitrile, vinyl ethers, maleic acid, maleic acid esters, maleic anhydride, cinnamic acid, vinyl chloride and vinyl acetate. These resins may be used in a combination of two or more thereof.

The image-forming layer preferably contains the pigment in an amount of 30 to 70 mass % (i.e., weight %), more preferably from 30 to 50 mass %. Also, the image-forming layer preferably contains the resin in an amount of 70 to 30 mass %, more preferably from 70 to 40 mass %.

The image-forming layer may contain the following components (1) to (3) as other components.

(1) Waxes

The waxes include mineral waxes, natural waxes and synthetic waxes. Examples of the mineral waxes include petroleum waxes such as paraffin wax, microcrystalline wax, ester wax and oxidized wax; montan wax; ozokerite; and ceresine. Among these, paraffin wax is preferred. The paraffin wax is separated from petroleum and various products different in the melting point are available on the market.

Examples of the natural waxes include plant waxes such as carnauba wax, Japan wax, ouriculy was and espurto wax, and animal waxes such as beeswax, insect wax, shellac wax and spermaceti wax.

The synthetic wax is generally used as a lubricant and usually comprises a higher fatty acid-base compound. Examples of the synthetic waxes include the followings.

1) Fatty Acid Wax

Linear saturated fatty acids represented by the following formula:

CH₃(CH₂)ₙCOOH

wherein n represents an integer of 6 to 28. Specific examples thereof include a stearic acid, a behenic acid, a palmitic acid, a 12-hydroxystearic acid and an azelaic acid.

In addition, metal salts (e.g., K. Ca, Zn, Mg) of the above-describe fatty acids can be used.

2) Fatty Acid Ester Wax

Specific examples of the ester of the above-described fatty acids include ethyl stearate, lauryl stearate, ethyl behenate, hexyl behenate and behenyl myristate

3) Fatty Acid Amide Wax

Specific examples of the amide of the above-described fatty acids include stearic acid amide and lauric acid amide.

4) Aliphatic Alcohol Wax

Linear saturated aliphatic alcohols represented by the following formula:

CH₃(CH₂)ₙOH

wherein n represents an integer of 6 to 28. Specific examples thereof include stearyl alcohol.

Among these synthetic waxes 1) to 4), higher fatty acid amides such as stearic acid amide and lauric acid amide are preferred. The above-described wax compounds may be used, if desired, individually or in appropriate combination.

(2) Plasticizer

The plasticizer is preferably an ester compound and examples thereof include phthalic acid esters such as dibutyl phthalate, di-n-octyl phthalate, di(2-ethylhexyl) phthalate, dinonyl phthalate, dilauryl phthalate, butyllauryl phthalate and butylbenzyl phthalate; aliphatic dibasic acid esters such as di(2-ethylhexyl) adipate and di(2-ethylhexyl) sebacate; phosphoric acid triesters such as tricresyl phosphate and tri(2-ethylhexyl) phosphate; polyol polyesters such as polyethylene glycol ester; and epoxy compounds such as epoxy fatty acid ester. These plasticizers are known. Among these, esters of vinyl monomer, particularly esters of acrylic acid or methacrylic acid, are preferred in view of improvement in the transfer sensitivity or transfer unevenness and in the control effect of elongation at break.

Examples of the ester compound of acrylic acid or methacrylic acid include polyethylene glycol dimethacrylate, 1,2,4-butanetriol trimethacrylate, trimethylolethane triacrylate, pentaerythritol acrylate, pentaerythritol tetraacrylate and dipentaerythritol polyacrylate.

The plasticizer may be a polymer. In particular, polyester is preferred because of its great addition effect and difficult diffusibility under storage conditions. Examples of the polyester include sebacic acid-based polyester and adipic acid-based polyester.

These additives contained in the image-forming layer are not limited thereto and the plasticizers may be used individually or in combination of two or more thereof.

If the content of the above-described additives in the image-forming layer is excessively large, the resolution of the transfer image may lower, the film strength of the image-forming layer itself may decrease or due to reduction in the adhesive strength between the light-to-heat conversion layer and the image-forming layer, an unexposed area may be transferred to the image-receiving sheet. In view of these points, the wax content is preferably from 0.1 to 30 mass %, more preferably from 1 to 20 mass %, based on the total solid content in the image-forming layer. The plasticizer content is preferably from 0.1 to 20 mass %, more preferably from 0.1 to 10 mass %, based on the total solid content in the image-forming layer.

(3) Others

In addition to the above-described components, the image-forming layer may contain a surfactant, an inorganic or organic fine particle (e.g., metal powder, silica gel), an oil (e.g., linseed oil, mineral oil) , a thickener, an antistatic agent and the like. Except for the case of obtaining a black image, when a substance capable of absorbing light at the wavelength of the light source used in the image recording is incorporated, the energy necessary for the transfer can be reduced. The substance capable of absorbing light at the wavelength of the light source may be either a pigment or a dye, however, in the case of obtaining a color image, use of an infrared light source such as semiconductor laser for the image recording and use of a dye having small absorption in the visible region but large absorption at the wavelength of the light source are preferred in view of the color reproduction. Examples of the near infrared dye include the compounds described in JP-A-3-103476.

The image-forming layer can be provided by preparing a coating solution having dissolved or dispersed therein the pigment, the binder and the like, applying the coating solution onto a light-to-heat conversion layer (when a heat-sensitive peeling layer which is described later is provided on the light-to-heat conversion layer, on the heat-sensitive peeling layer), and drying the solution. Examples of the solvent used in the preparation of the coating solution include n-propyl alcohol, methyl ethyl ketone, propylene glycol monomethyl ether (MFG), methanol and water. The coating and the drying can be performed using ordinary coating and drying methods.

On the light-to-heat conversion layer of the thermal transfer sheet, a heat-sensitive peeling layer containing a heat-sensitive material which generates a gas or releases adhered water or the like under the action of heat generated from the light-to-heat conversion layer and thereby weakens the adhesive strength between the light-to-heat conversion layer and the image-forming layer, may be provided. For the heat-sensitive material, a compound (a polymer or a low molecular compound) capable of decomposing or denaturing by itself due to heat and generating a gas, a compound (a polymer or a low molecular compound) having absorbed or adsorbed therein a fairly large amount of an easily vaporizable gas such as moisture, or the like may be used. These may be used in combination.

Examples of the polymer capable of decomposing or denaturing due to heat and generating a gas include self-oxidizing polymers such as nitrocellulose; halogen-containing polymers such as chlorinated polyolefin, chlorinated rubber, polychlorinated rubber, polyvinyl chloride and polyvinylidene chloride; acrylic polymers such as polyisobutyl methacrylate having adsorbed therein a volatile compound (e.g., moisture); cellulose esters such as ethyl cellulose having adsorbed therein a volatile compound (e.g., moisture) ; and natural polymer compounds such as gelatin having adsorbed therein a volatile compound (e.g., moisture). Examples of the low molecular compound capable of decomposing or denaturing due to heat and generating a gas include compounds which undergo an exothermic decomposition and thereby generate a gas, such as diazo compound and azide compound.

The temperature at which the heat-sensitive material decomposes or denatures due to heat is preferably 280° C. or less, more preferably 230° C. or less.

In the case where a low molecular compound is used as the heat-sensitive material of the heat-sensitive peeling layer, the compound is preferably combined with a binder. The binder used here may be the above-described polymer capable of decomposing or denaturing by itself due to heat and generating a gas, or may be an ordinary binder lacking in this property. When the heat-sensitive low molecular compound is used in combination with a binder, the mass ratio of the former to the latter is preferably from 0.02:1 to 3:1, more preferably from 0.05:1 to 2:1. The heat-sensitive peeling layer preferably covers almost the entire surface of the light-to-heat conversion layer. The thickness thereof is generally from 0.03 to 1 μm, preferably from 0.05 to 0.5 μm.

In the case of a thermal transfer sheet having a construction such that a light-to-heat conversion layer, a heat-sensitive peeling layer and an image-forming layer are stacked in this order on a support, the heat-sensitive peeling layer undergoes decomposition or denaturing due to heat transmitted from the light-to-heat conversion layer and generates a gas. By this decomposition or gas generation, the heat-sensitive peeling layer is partially lost or a cohesive destruction takes place within the heat-sensitive peeling layer, as a result, the adhesive strength between the light-to-heat conversion layer and the image-forming layer decreases. Accordingly, depending on the behavior of the heat-sensitive peeling layer, a part of the heat-sensitive peeling layer may adhere to the image-forming layer and appear on the finally formed image, giving rise to color mixing of the image. Because of this, in order to ensure that color mixing is not visually perceivable in the formed image even if the above-described transfer of the heat-sensitive peeling layer takes place, the heat-sensitive peeling layer is preferably almost colorless, that is, highly transmissive to visible light. Specifically, the light absorption coefficient of the heat-sensitive peeling layer is, for visible light, 50% or less, preferably 10% or less.

The thermal transfer sheet may also have a construction such that in place of independently forming the heat-sensitive peeling layer, the above-described heat-sensitive material is added to the coating solution for the light-to-heat conversion layer and the formed light-to-heat conversion layer serves as a light-to-heat conversion layer and as a heat-sensitive peeling layer at the same time.

The outermost layer of the thermal transfer sheet in the side where the image-forming layer is provided preferably has a static friction coefficient of 0.35 or less, more preferably 0.20 or less. When the outermost layer is rendered to have a static friction coefficient of 0.35 or less, the roll can be prevented from contaminating at the time of transporting the thermal transfer sheet and the formed image can have high quality. The coefficient of static friction is measured according to the method described in JP-A-2001-47753, paragraph (0011).

The Smooster value (i.e., “Smooster Smoothness” defined in JAPAN TAPPI No.5) on the surface of the image-forming layer is preferably from 0.5 to 50 mmHg (≈0.0665 to 6.65 kPa) at 23° C. and 55% RH and at the same time, the Ra value is preferably from 0.05 to 0.4 μm. With these values, a large number of microscopic voids formed on the contact surface to inhibit the contacting between the image-receiving layer and the image-forming layer can be reduced and this is advantageous in view of transfer and in turn image quality. The Ra value can be measured according to JIS B0601 using a surface roughness meter (Surfcom, manufactured by Tokyo Seimitsu Co., Ltd.). The surface hardness of the image-forming layer is preferably 10 g or more with a sapphire needle. One second after the earth connection of the thermal transfer sheet which is electrified according to U.S. Federal Test Standard 4046, the charge potential of the image-forming layer is preferably from −100 to 100 V. The surface resistance of the image-forming layer is preferably 10⁹ Ω or less at 23° C. and 55% RH.

The image-receiving sheet which is used in combination with the above-described thermal transfer sheet is described below.

[Image-receiving sheet]

(Layer Construction)

The image-receiving sheet usually has a construction such that one or more image-receiving layer is provided on a support and if desired, any one or more of a cushion layer, a peeling layer and an interlayer is provided between the support and the image-receiving layer. In view of the transportation, the image-receiving sheet preferably has a back layer on the surface of the support in the side opposite the image-receiving layer.

(Support)

Examples of the support include normal sheet-form substrates such as plastic sheet, metal sheet, glass sheet, resin coated paper, paper and various composite bodies. Examples of the plastic sheet include polyethylene terephthalate sheet, polycarbonate sheet, polyethylene sheet, polyvinyl chloride sheet, polyvinylidene chloride sheet, polystyrene sheet, styrene-acrylonitrile sheet and polyester sheet. Examples of the paper include printing paper and coated paper.

The support preferably has fine voids because the image quality can be improved, and this support can be manufactured as follows. For example, a thermoplastic resin and a filler comprising an inorganic pigment, a polymer incompatible with the thermoplastic resin and the like are mixed, the obtained mixture melt is formed into a single-layer or multi-layer film using a melt extruder and the film is uniaxially or biaxially stretched. In this case, the void percentage is determined by the resin and filler selected, the mixing ratio, the stretching conditions and the like.

For the above-described thermoplastic resin, polyolefin resins such as polypropylene, and polyethylene terephthalate resins are preferred because of their high crystallinity, good stretching property and easiness in the formation of voids. It is preferred to use the polyolefin resin or polyethylene terephthalate resin as the main component and appropriately use a small amount of another thermoplastic resin in combination. The inorganic pigment used as the filler preferably has an average particle size of 1 to 20 μm and examples of the inorganic pigment which can be used include calcium carbonate, clay, kieselguhr, titanium oxide, aluminum hydroxide and silica. As for the incompatible resin used as the filler, in the case where the thermoplastic resin is polypropylene, polyethylene terephthalate is preferably used in combination as the filler. The support having fine voids is described in detail in JP-A-2001-105752.

In the support, the content of the filler such as inorganic pigment is generally on the order of 2 to 30% by volume.

In the image-receiving sheet, the thickness of the support is usually from 10 to 400 μm, preferably from 25 to 200 μm. The surface of the support may be subjected to a surface treatment such as corona discharge treatment or glow discharge treatment so as to elevate the adhesive property with the image-receiving layer (or cushion layer) or to elevate the adhesive property with the image-forming layer of the thermal transfer sheet.

(Image-Receiving Layer)

Since the image-forming layer is transferred and fixed on the surface of the image-receiving sheet, one or more image-receiving layer is preferably provided on the support. The image-receiving layer is preferably formed of mainly an organic polymer binder. This binder is preferably a thermoplastic resin and may be appropriately selected and used from various resins described above as the polymer or its composition for use in the image-receiving layer. For obtaining an appropriate adhesive strength with the image-forming layer, the binder of the image-forming layer is preferably a polymer having a glass transition temperature (Tg) of less than 90° C. For this purpose, it is also possible to add a plasticizer to the image-forming layer. Furthermore, the binder polymer preferably has a Tg of 30° C. or more so as to prevent blocking between sheets. When the humidity is conditioned at 25° C. to 50% RH, the Tg of this binder polymer is, as described above, preferably from 6 to 67° C., preferably from 44 to 56° C. In particular, from the standpoint of improving the adhesive property with the image-forming layer at the laser recording and elevating the sensitivity or image strength, the binder polymer for use in this image-receiving layer is preferably the same as or analogous to the binder polymer used in the image-forming layer.

It is preferred that the Smooster value on the image-receiving layer surface is from 0.5 to 50 mmHg (≈0.0665 to 6.65 kPa) at 23° C. and 55% RH and at the same time, the Ra value is from 0.05 to 0.4 μm. With these values, a large number of microscopic voids formed on the contact surface to inhibit the contacting between the image-receiving layer and the image-forming layer can be reduced and this is advantageous in view of transfer and in turn image quality. The Ra value can be measured according to JIS B0601 using a surface roughness meter (Surfcom, manufactured by Tokyo Seimitsu Co., Ltd.). One second after the earth connection of the image-receiving sheet which is electrified according to U.S. Federal Test Standard 4046, the charge potential of the image-receiving layer is preferably from −100 to 100 V. The surface resistance of the image-receiving layer is preferably 10⁹ Ω or less at 23° C. and 55% RH. The coefficient of static friction is preferably 0.2 or less on the surface of the image-receiving layer and the surface energy on the surface of the image-receiving layer is preferably from 23 to 35 mg/m².

In the case of once forming an image on the image-receiving layer and re-transferring the image to printing paper or the like, at least one image-receiving layer is preferably formed of a photocurable material. Examples of the composition for the photocurable material include a combination of a) a photopolymerizable monomer comprising at least one polyfunctional vinyl or vinylidene compound capable of forming a photopolymer by the addition polymerization, b) an organic polymer, c) a photopolymerization initiator and if desired, additives such as thermopolymerization inhibitor. For the polyfunctional vinyl monomer, an unsaturated ester of polyol, particularly an ester of acrylic acid or methacrylic acid, such as ethylene glycol diacrylate, pentaerythritol tetraacrylate, is used.

Examples of the organic polymer include polymers described above as the polymer for the formation of the image-receiving layer. As for the photopolymerization inhibitor, a normal photoradical polymerization initiator such as benzophenone or Michler's ketone is used in a proportion of 0.1 to 20 mass % in the layer.

The thickness of the image-receiving layer is from 0.3 to 7 μm, preferably from 0.7 to 4 μm. When the thickness is 0.3 μm or more, a sufficiently high film strength can be ensured at the re-transfer to printing paper. When the thickness is 4 μm or less, the gloss of image after the re-transfer to printing paper can be suppressed and the approximation to a printed matter is improved.

(Other Layers)

A cushion layer may be provided between the support and the image-receiving layer. When a cushion layer is provided, the adhesive property between the image-forming layer and the image-receiving layer is improved at the thermal transfer using a laser and the image quality can be improved. Furthermore, even if foreign matters are mingled between the thermal transfer sheet and the image-receiving sheet at the recording, voids between the image-receiving layer and the image-forming layer are reduced in the size due to deformation activity of the cushion layer, as a result, the size of image defects such as white spot (i.e., clear spot) can also be made small. In addition, when an image is formed by the transfer and this image is transferred to separately prepared printing paper or the like, the image surface is deformed according to the irregularities on the paper surface and therefore, the transferability of the image-receiving layer can be improved. Furthermore, by reducing the gloss of the transferee material, the approximation to a printed matter can be improved.

The cushion layer has a structure easy to deform upon application of a stress onto the image-forming layer and for achieving the above-described effect, this layer is preferably formed of a material having a low modulus of elasticity, a material having rubber elasticity or a thermoplastic resin which is easily softened under heating. The elastic modulus of the cushion layer is preferably from 0.5 MPa to 1.0 GPa, more preferably from 1 MPa to 0.5 GPa, still more preferably from 10 to 100 MPa, at room temperature. Also, for burying foreign matters such as dust, the penetration (25° C., 100 g, 5 seconds) prescribed by JIS K2530 is preferably 10 or more. The glass transition temperature of the cushion layer is 80° C. or less, preferably 25° C. or less, and the softening point is preferably from 50 to 200° C. For adjusting these physical properties, for example, Tg, a plasticizer may be suitably added into the binder.

Specific examples of the material used as the binder of the cushion layer include polyethylene, polypropylene, polyester, styrene-butadiene copolymers, ethylene-vinyl acetate copolymers, ethylene-acryl copolymers, vinyl chloride-vinyl acetate copolymers, vinylidene chloride resin, plasticizer-containing vinyl chloride resin, polyamide resin and phenol resin, in addition to rubbers such as urethane rubber, butadiene rubber, nitrile rubber, acryl rubber and natural rubber.

The thickness of the cushion layer varies depending on the resin used and other conditions but is usually from 3 to 100 μm, preferably from 10 to 52 μm.

The image-receiving layer and the cushion layer must be bonded until the laser recording stage but for transferring the image to printing paper, these layers are preferably provided in the releasable state. In order to facilitate the peeling, a peeling layer having a thickness of approximately from 0.1 to 2 μm is preferably provided between the cushion layer and the image-receiving layer. If the film thickness is excessively large, the capability of the cushion layer cannot be easily brought out. Therefore, the film thickness must be adjusted depending on the kind of the peeling layer.

Specific examples of the binder of the peeling layer include polyolefin, polyester, polyvinyl acetal, polyvinyl formal, polyparabanic acid, polymethyl methacrylate, polycarbonate, ethyl cellulose, nitrocellulose, methyl cellulose, carboxymethyl cellulose, hydroxypropyl cellulose, polyvinyl alcohol, polyvinyl chloride, urethane resin, fluorine-containing resin, styrenes such as polystyrene and acrylonitrile styrene, crosslinked products of these resins, thermosetting resins having a Tg of 65° C. or more, such as polyamide, polyimide, polyether imide, polysulfone, polyether sulfone and aramid and cured products of these resins. The curing agent used here can be a general curing agent such as isocyanate and melamine.

On considering the above-described properties in the selection of the binder of the peeling layer, polycarbonate, acetal and ethyl cellulose are preferred in view of storability. Furthermore, an acrylic resin is preferably used in the image-forming layer, because good peelability can be provided at the time of re-transferring the image thermally transferred using a laser.

Also, another layer which is extremely reduced in the adhesive property with the image-forming layer on cooling may be used as the peeling layer. Specifically, a layer mainly comprising a heat-fusible compound such as wax or binder, or a thermoplastic resin may be provided.

Examples of the heat-fusible compound include the substances described in JP-A-63-193886. In particular, microcrystalline wax, paraffin wax and carnauba wax are preferred. As for the thermoplastic resin, preferred examples thereof include ethylene-based copolymers (e.g., ethylene-vinyl acetate resin) and cellulose-based resins.

In these peeling layers, additives such as higher fatty acid, higher alcohol, higher fatty acid ester, amide and higher amine may be added, if desired.

In another construction of the peeling layer, the layer is fused or softened on heating and undertakes cohesive destruction by itself, thereby exhibiting peelability. This peeling layer preferably contains a supercooling substance.

Examples of the supercooling substance include poly-ε-caprolactone, polyoxyethylene, benzotriazole, tribenzylamine and vanillin.

In still another construction of the peeling layer, a compound capable of reducing the adhesive property with the image-receiving layer is incorporated. Examples of this compound include silicone-based resins such as silicone oil; fluorine-containing resins such as Teflon and fluorine-containing acrylic resin; polysiloxane resin; acetal-based resins such as polyvinyl butyral, polyvinyl acetal and polyvinyl formal; solid waxes such as polyethylene wax and amide wax; and fluorine-based or phosphoric acid ester-based surfactants.

The peeling layer can be formed by a method where the above-described raw materials are dissolved or dispersed like a latex in a solvent and the solution or dispersion is coated on the cushion layer using a coating method such as blade coater, roll coater, bar coater, curtain coater or gravure coater, or an extrusion lamination method by hot melting. The peeling layer can also be formed by a method where the raw materials dissolved or dispersed like a latex in a solvent is coated on a temporary base using the above-described method, the coating is attached to the cushion layer, and the temporary base is peeled off.

The image-receiving sheet combined with the thermal transfer sheet may have a structure such that the image-receiving layer serves also as the cushion layer. In this case, the image-receiving sheet may have a structure of support/cushiony image-receiving layer or a structure of support/undercoat layer/cushiony image-receiving layer. Also in this case, the cushiony image-receiving layer is preferably provided in the peelable state so that the re-transfer to the printing paper can be facilitated. If the case is so, the image after the re-transfer to printing paper can be an image having excellent glossiness.

The thickness of the cushiony image-receiving layer is from 5 to 100 μm, preferably from 10 to 40 μm.

In the image-receiving sheet, a back layer is preferably provided on the surface of the support in the side opposite the surface where the image-receiving layer is provided, because the image-receiving sheet can be improved in the transportation property. For the purpose of attaining good transportation within the recording device, the back layer preferably contains an antistatic agent using a surfactant or tin oxide fine particle, and a matting agent using silicon oxide or PMMA particle.

These additives can be added not only to the back layer but also, if desired, to the image-receiving layer or other layers. The kind of additive varies depending on the purpose and cannot be indiscriminately specified, however, for example, in the case of a matting agent, particles having an average particle size of 0.5 to 10 μm may be added to the layer in a proportion of approximately from 0.5 to 80%. The antistatic agent may be appropriately selected from various surfactants and electrically conducting agents and used such that the surface resistance of the layer is 10¹² Ω or less, preferably 10⁹ Ω or less, under the conditions of 23° C. and 50% RH.

For the binder used in the backcoat layer, a general-purpose polymer may be used, such as gelatin, polyvinyl alcohol, methyl cellulose, nitrocellulose, acetyl cellulose, aromatic polyamide resin, silicone resin, epoxy resin, alkyd resin, phenol resin, melamine resin, fluororesin, polyimide resin, urethane resin, acrylic resin, urethane-modified silicone resin, polyethylene resin, polypropylene resin, polyester resin, Teflon resin, polyvinyl butyral resin, vinyl chloride-based resin, polyvinyl acetate, polycarbonate, organic boron compounds, aromatic esters, fluorinated polyurethane and polyether sulfone.

When a crosslinkable water-soluble binder is used as the binder of the backcoat layer, this is effective in preventing the matting agent from powder-falling or improving the scratch resistance of the back layer. This use is also greatly effective on the blocking during storage.

As for the crosslinking means, heat, active ray and pressure may be used individually or in combination without any particular limitation according to the properties of the crosslinking agent used. Depending on the case, an arbitrary adhesive layer may be provided on the support in the side where the back layer is provided, so that the support can be imparted with adhesive property.

For the matting agent which is preferably added to the back layer, an organic or inorganic fine particle can be used. Examples of the organic matting agent include a fine particle of radical polymerization-type polymer such as polymethyl methacrylate (PMMA), polystyrene, polyethylene and polypropylene, and a fine particle of condensed polymer such as polyester and polycarbonate.

The back layer is preferably provided in a coated amount of approximately from 0.5 to 5 g/m². If the coated amount is less than 0.5 g/m², the coatability is unstable and problems such as powder-falling of the matting agent are readily caused, whereas if it exceeds 5 g/m², the particle size of the suitable matting agent becomes very large and the image-receiving layer surface is embossed by the back layer during storage, as a result, missing or uneven formation of a recorded image is liable to occur particularly in the thermal transfer of transferring a thin-film image-forming layer.

The matting agent preferably has a number average particle size 2.5 to 20 μm larger than the film thickness of the back layer comprising only a binder. In the matting agent, particles having a particle size of 8 μm or more must be present in an amount of 5 mg/m² or more, preferably from 6 to 600 mg/m². By containing the matting agent as such, the foreign matter failure can be improved. Also, by using a matting agent having a narrow particle size distribution such that the value (σ/rn (=coefficient of variation in the particle size distribution)) obtained by dividing the standard deviation of the particle size distribution by the number average particle size is 0.3 or less, the defect encountered in the case of using particles having an extremely large particle size can be improved and moreover, a desired performance can be obtained with a smaller amount added. This coefficient of variation is preferably 0.15 or less.

In the back layer, an antistatic agent is preferably added so as to prevent the adhesion of foreign matters due to frictional electrification with a transportation roll. Examples of the antistatic agent which can be used include cationic surfactants, anionic surfactants, nonionic surfactants, polymer antistatic agents, electrically conducting fine particles and compounds over a wide range described in 11290 no Kagaku Shohin (11290 Chemical Products), Kagaku Kogyo Nippo Sha, pp. 875-876.

Among these substances as the antistatic agent which can be used in combination in the back layer, preferred are metal oxides such as carbon black, zinc oxide, titanium oxide and tin oxide, and electrically conducting fine particles such as organic semiconductor. In particular, the electrically conducting fine particle is preferred because the antistatic agent does not dissociate from the back layer and the antistatic effect can be stably obtained independently of the environment.

In the back layer, various activators or release agents such as silicone oil and fluororesin may be added so as to impart coatability or releasability.

The back layer is particularly preferred when the cushion layer and the image-receiving layer each has a softening point of 70° C. or less as measured by TMA (thermomechanical analysis).

The TMA softening point is determined by elevating the temperature of an object to be measured at a constant temperature-rising rate while applying a constant load, and observing the phase of the object. In the present invention, the temperature where the phase of the object to be measured starts changing is defined as the TMA softening point. The measurement of the softening point by TMA can be performed using an apparatus such as Thermoflex manufactured by Rigaku Denki Sha.

In the image formation, the thermal transfer sheet and the image-receiving sheet can be used as a laminate obtained by superposing the image-forming layer of the thermal transfer sheet and the image-receiving layer of the image-receiving sheet.

The laminate of the thermal transfer sheet and the image-receiving sheet can be formed by various methods. For example, the laminate can be easily obtained by superposing the image-forming layer of the thermal transfer sheet and the image-receiving layer of the image-receiving sheet and passing these sheets between pressure and heating rollers. In this case, the heating temperature is preferably 160° C. or less, or 130° C. or less.

Another suitable method for obtaining the laminate is the above-described vacuum adhesion method. The vacuum adhesion method is a method where an image-receiving sheet is first wound around a drum having provided thereon a suction hole for vacuumization and then, a thermal transfer sheet having a slightly larger size than the image-receiving sheet is subjected to vacuum adhesion with the image-receiving sheet while uniformly expelling air by a squeeze roller. Other than this, a method where an image-receiving sheet is attached to a metal drum while mechanically pulling the image-receiving sheet and further thereon, a thermal transfer sheet is attached similarly while mechanically pulling the thermal transfer sheet, thereby adhering these sheets, may also be used. Among these methods, a vacuum adhesion method is preferred because the temperature of heat roller and the like needs not be controlled and the layers can be rapidly and uniformly stacked with ease.

### EXAMPLE

The present invention is described in greater detail below by referring to Examples, however, the present invention should not be construed as being limited thereto. In the Examples, unless otherwise indicated, the “parts” means “parts by mass”.

### Example 1-1

### Preparation of Thermal Transfer Sheet K (black)

[Formation of Back Layer]

Preparation of Coating Solution for Back First Layer:

| | |
|---|---|
| Water Dispersion of Acrylic Resin | 2 parts |
| (JULYMER ET410, solid content: 20 | |
| mass %, Nippon Junyaku K.K.) | |
| Antistatic agent (water dispersion of | 7.0 parts |
| tin oxide-antimony oxide) (average | |
| particle size: 0.1 μm, 17 mass %) | |
| Polyoxyethylene phenyl ether | 0.1 part |
| Melamine compound (SUMITIC Resin M-3, | 0.3 parts |
| produced by Sumitomo Chemical Co., | |
| Ltd.) | |
| Distilled water to make a total of | 100 parts |

Formation of Back First Layer:

One surface (back surface) of a 75 μm-thick biaxially stretched polyethylene terephthalate support (Ra is 0.01 μm on both surfaces) was subjected to a corona treatment and the coating solution for the back first layer was coated thereon to a dry thickness of 0.03 μm and dried at 180° C. for 30 seconds to form a back first layer. The Young's modulus in the longitudinal direction of the support was 450 kg/mm² (≈4.4 GPa) and the Young's modulus in the cross direction was 500 kg/mm² (≈4.9 GPa). The F-5 value in the longitudinal direction of the support was 10 kg/mm² (≈98 MPa) and the F-5 value in the cross direction of the support was 13 kg/mm² (≈127.4 MPa). The heat shrinkage percentage at 100° C. for 30 minutes of the support was 0.3% in the longitudinal and 0.1% in the cross directions. The breaking strength was 20 kg/mm² (≈196 MPa) in the longitudinal direction and 25 kg/mm² (≈245 MPa) in the cross direction. The elastic modulus was 400 kg/mm² (≈3.9 GPa).

Preparation of Coating Solution for Back Second Layer:

| | |
|---|---|
| Polyolefin (CHEMIPEARL S-120, | 3.0 parts |
| 27 mass %, produced by Mitsui | |
| Petrochemical Industries, Ltd.) | |
| Antistatic agent (water dispersion of | 2.0 parts |
| tin oxide-antimony oxide) (average | |
| particle size: 0.1 μm, 17 mass %) | |
| Colloidal Silica C, 20 mass %, produced | 2.0 parts |
| by Nissan Chemicals Industries, Ltd.) | |
| Epoxy compound (DINACOL EX-614B, | 0.3 parts |
| produced by Nagase Kasei K.K.) | |
| Distilled water to make a total of | 100 parts |

Formation of Back Second Layer:

The coating solution for the back second layer was coated on the back first layer to a dry thickness of 0.03 μm and then dried at 170° C. for 30 seconds to form a back second layer.

1) Preparation of Coating Solution for Light-to-Heat Conversion Layer:

The components shown below were mixed while stirring with a stirrer to prepare a coating solution for the light-to-heat conversion layer.

Composition of Coating Solution for Light-to-Heat Conversion Layer:

| | |
|---|---|
| Infrared light absorbing dye (“NK-2014” | 7.6 parts |
| produced by Nippon Kanko Shikiso Co., Ltd., | |
| a cyanine dye having a structure shown below) | |
| 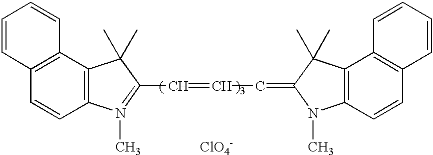 | |
| Polyimide resin having a structure shown below | 29.3 parts |
| (“RIKACOAT SN-20F”, produced by Shin Nippon Rika K.K., | |
| thermal decomposition temperature: | |
| 510° C.) | |
| 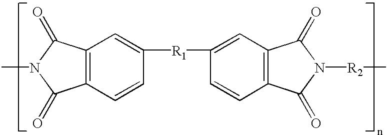 | |
| (wherein R₁ represents SO₂, R₂ represents | |
| 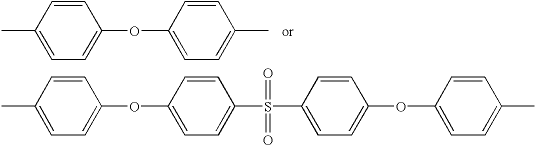 | |
| Exxon Naphtha | 5.8 parts |
| N-Methylpyrrolidone (NMP) | 1,500 parts |
| Methyl ethyl ketone | 360 parts |
| Surfactant (“Megafac F-176” produced by | 0.5 parts |
| Dainippon Ink & Chemicals Inc., F-containing surfactant) | |
| Matting agent dispersion having a composition shown below | 14.1 parts |

Matting Agent Dispersion:

| | |
|---|---|
| N-Methyl-2-pyrrolidone (NMP) | 69 parts |
| Methyl ethyl ketone | 20 parts |
| Styrene acrylic resin (“JONCRYL 611”, | 3 parts |
| produced by Johnson Polymer K.K.) | |
| SiO₂ particle (“SEAHOSTAR KEP150”, | 8 parts |
| silica particle, produced by Nippon | |
| Shokubai K.K.) | |

2) Formation of Light-to-Heat Conversion Layer on Support Surface

On one surface of a 75 μm-thick polyethylene terephthalate film (support), the coating solution for the light-to-heat conversion layer prepared above was coated using a wire bar and then, the coating was dried for 2 minutes in an oven at 120° C. to form a light-to-heat conversion layer on the support. The optical density of the obtained light-to-heat conversion layer at a wavelength of 808 nm was measured using a UV-spectrophotometer UV-240 manufactured by Shimadzu Corporation and found to be OD=1.03. The cross-section of the light-to-heat conversion layer was observed through a scanning electron microscope and the layer thickness was found to be 0.3 μm on average.

3) Preparation of Coating Solution for Black Image-Forming Layer

The components shown below were charged into a mill of a kneader and a dispersion pretreatment was performed by adding a shear force while adding a slight amount of a solvent. To the obtained dispersion, the solvent was further added to finally have the following composition, and the resulting solution was dispersed in a sand mill for 2 hours to obtain a pigment dispersion mother solution.

[Composition of Black Pigment Dispersion Mother Solution]

Composition 1:

| | |
|---|---|
| Polyvinyl butyral (“Eslec B BL-SH”, | 12.6 parts |
| produced by Sekisui Chemical Co., | |
| Ltd.) | |
| Pigment Black 7 (carbon black, C.I. | 4.5 parts |
| No. 77266) (“Mitsubishi Carbon Black #5”, | |
| produced by Mitsubishi Chemical, | |
| PVC blackness: 1) | |
| Dispersion aid (“SOLSPERSE S-20000”, | 0.8 parts |
| produced by ICI) | |
| n-Propyl alcohol | 79.4 parts |

Composition 2:

| | |
|---|---|
| Polyvinyl butyral (“Eslec B BL-SH”, | 12.6 parts |
| produced by Sekisui Chemical Co., | |
| Ltd.) | |
| Pigment Black 7 (carbon black, C.I. | 0.8 parts |
| No. 77266) (“Mitsubishi Carbon Black | |
| MA100”, produced by Mitsubishi | |
| Chemical, PVC blackness: 1) | |
| Dispersion aid (“SOLSPERSE S-20000”, | 0.8 parts |
| produced by ICI) | |
| n-Propyl alcohol | 79.4 parts |

Then, the components shown below were mixed while stirring with a stirrer to prepare a coating solution for the black image-forming layer.

[Composition of Coating Solution for Black Image-Forming Layer]

| | |
|---|---|
| Black pigment dispersion mother | 185.7 parts |
| solution prepared above [Composition | |
| 1:Composition 2 = 70:30 (by parts)] | |
| Polyvinyl butyral (“Eslec B BL-SH”, | 11.9 parts |
| produced by Sekisui Chemical Co., | |
| Ltd.) | |
| Wax-based compounds: | |
| (Stearic acid amide, “NEWTRON 2”, | 1.7 parts |
| produced by Nippon Seika) | |
| (Behenic acid amide, “DIAMID BM”, | 1.7 parts |
| produced by Nippon Kasei) | |
| (Lauric acid amide, “DIAMID Y”, | 1.7 parts |
| produced by Nippon Kasei) | |
| (Palmitic acid amide, “DIAMID KP”, | 1.7 parts |
| produced by Nippon Kasei) | |
| (Erucic acid amide, “DIAMID L-200”, | 1.7 parts |
| produced by Nippon Kasei) | |
| (Oleic acid amide, “DIAMID O-200”, | 1.7 parts |
| produced by Nippon Kasei) | |
| Rosin (“KE-311”, produced by Arakawa | 11.4 parts |
| Kagaku) (component: resin acid 80-97%, | |
| resin acid components: abietinic acid | |
| 30-40%, neoabitienic acid 10-20%, | |
| dihydroabitienic acid 14%, | |
| tetrahydroabitienic acid 14%) | |
| Surfactant (“Megafac F-176PF”, solid | 2.1 parts |
| content: 20%, produced by Dainippon | |
| Ink & Chemicals Inc.) | |
| Inorganic pigment (“MEK-ST” 30% methyl | 7.1 parts |
| ethyl ketone solution, produced by | |
| Nissan Chemicals Industries, Ltd.) | |
| n-Propyl alcohol | 1,050 parts |
| Methyl ethyl ketone | 295 parts |

The particles in the thus-obtained coating solution for the black image-forming layer were measured by a particle size distribution meter employing a laser scattering system, as a result, the average particle size was 0.25 μm and the particles of 1 μm or more occupied 0.5%.

4) Formation of Black Image-Forming Layer on Surface of Light-to-Heat Conversion Layer

On the surface of the light-to-heat conversion layer formed above, the coating solution for the black image-forming layer prepared above was coated using a wire bar over 1 minute and then, the coating was dried for 2 minutes in an oven at 100° C. to form a black image-forming layer on the light-to-heat conversion layer. In this way, a thermal transfer sheet (hereinafter referred to as “Thermal Transfer Sheet K”; similarly, the thermal transfer sheets having provided therein a yellow image-forming layer, a magenta image-forming layer or a cyan image-forming layer are referred to as “Thermal Transfer Sheet Y”, “Thermal Transfer Sheet M” and “Thermal Transfer Sheet C”, respectively).

The optical density (optical density: OD) of the black image-forming layer of Thermal Transfer Sheet K was measured by a Macbeth densitometer “TD-904” (W filter) and found to be OD=0.91. Also, the thickness of the black image-forming layer was measured and found to be 0.60 μm on average.

The obtained image-forming layer had the following physical properties.

The surface hardness of the image-forming layer, which is preferably 10 g or more with a sapphire needle, was 200 g or more.

The Smooster value on the surface, which is preferably from 0.5 to 50 mmHg (≈0.0665 to 6.65 kPa) at 23° C. and 55% RH, was 9.3 mmHg (≈1.24 kPa).

The coefficient of static friction on the surface, which is preferably 0.2 or less, was 0.08.

The surface energy was 29 mJ/m², the contact angle to water was 94.8°, the reflection optical density was 1.82, the layer thickness was 0.60 μm and the OD/layer thickness was 3.03.

When the recording was performed using laser light having a light intensity of 1,000 W/mm² or more on the exposure surface at a linear velocity of 1 m/sec or more, the deformation percentage of the light-to-heat conversion layer was 168%.

Manufacture of Thermal Transfer Sheet Y:

Thermal Transfer Sheet Y was manufactured in the same manner as in the manufacture of Thermal Transfer Sheet K except for using the coating solution for yellow image-forming layer having a composition shown below in place of the coating solution for black image-forming layer in the manufacture of Thermal Transfer Sheet K. The image-forming layer of Thermal Transfer Sheet Y obtained had a layer thickness of 0.42 μm.

[Composition of Yellow Pigment Dispersion Mother Solution]

Yellow Pigment Composition 1:

| | |
|---|---|
| Polyvinyl butyral (“Eslec B BL-SH”, | 7.1 parts |
| produced by Sekisui Chemical Co., | |
| Ltd.) | |
| Pigment Yellow 180 (C.I. No. 21290) | 12.9 parts |
| (“Novoperm Yellow P-HG”, produced by | |
| Clariant Japan) | |
| Dispersion aid (“SOLSPERSE S-20000”, | 0.6 parts |
| produced by ICI) | |
| n-Propyl alcohol | 79.4 parts |

[Composition of Yellow Pigment Dispersion Mother Solution]

Yellow Pigment Composition 2:

| | |
|---|---|
| Polyvinyl butyral (“Eslec B BL-SH”, | 7.1 parts |
| produced by Sekisui Chemical Co., | |
| Ltd.) | |
| Pigment Yellow 139 (C.I. No. 56298) | 12.9 parts |
| (“Novoperm Yellow M2R 70”, produced by | |
| Clariant Japan) | |
| Dispersion aid (“SOLSPERSE S-20000”, | 0.6 parts |
| produced by ICI) | |
| n-Propyl alcohol | 79.4 parts |

[Composition of Coating Solution for Yellow Image-Forming Layer]

| | |
|---|---|
| Yellow pigment dispersion mother | 126 parts |
| solution prepared above [Yellow | |
| Pigment Composition 1:Yellow Pigment | |
| Composition 2 = 95:5 (by parts)] | |
| Polyvinyl butyral (“Eslec B BL-SH”, | 4.6 parts |
| produced by Sekisui Chemical Co., | |
| Ltd.) | |
| Wax-based compounds: | |
| (Stearic acid amide, “NEWTRON 2”, | 0.7 parts |
| produced by Nippon Seika) | |
| (Behenic acid amide, “DIAMID BM”, | 0.7 parts |
| produced by Nippon Kasei) | |
| (Lauric acid amide, “DIAMID Y”, | 0.7 parts |
| produced by Nippon Kasei) | |
| (Palmitic acid amide, “DIAMID KP”, | 0.7 parts |
| produced by Nippon Kasei) | |
| (Erucic acid amide, “DIAMID L-200”, | 0.7 parts |
| produced by Nippon Kasei) | |
| (Oleic acid amide, “DIAMID O-200”, | 0.7 parts |
| produced by Nippon Kasei) | |
| Nonionic surfactant (“CHEMISTAT 1100”, | 0.4 parts |
| produced by Sanyo Kasei) | |
| Rosin (“KE-311”, produced by Arakawa | 24 parts |
| Kagaku) (component: resin acid 80-97%, | |
| resin acid components: abietinic acid | |
| 30-40%, neoabitienic acid 10-20%, | |
| dihydroabitienic acid 14%, | |
| tetrahydroabitienic acid 14%) | |
| Surfactant (“Megafac F-176PF”, solid | 0.8 parts |
| content: 20%, produced by Dainippon | |
| Ink & Chemicals Inc.) | |
| n-Propyl alcohol | 793 parts |
| Methyl ethyl ketone | 198 parts |

The obtained image-forming layer had the following physical properties.

The surface hardness of the image-forming layer, which is preferably 10 g or more with a sapphire needle, was 200 g or more.

The Smooster value on the surface, which is preferably from 0.5 to 50 mmHg (≈0.0665 to 6.65 kPa) at 23° C. and 55% RH, was 2.3 mmHg (≈0.31 kPa).

The coefficient of static friction on the surface, which is preferably 0.2 or less, was 0.1.

The surface energy was 24 mJ/m², the contact angle to water was 108.1°, the reflection optical density was 1.01, the layer thickness was 0.42 μm and the OD/layer thickness was 2.40.

When the recording was performed using laser light having a light intensity of 1,000 W/mm² or more on the exposure surface at a linear velocity of 1 m/sec or more, the deformation percentage of the light-to-heat conversion layer was 150%.

Manufacture of Thermal Transfer Sheet M:

Thermal Transfer Sheet M was manufactured in the same manner as in the manufacture of Thermal Transfer Sheet K except for using the coating solution for magenta image-forming layer having a composition shown below in place of the coating solution for black image-forming layer in the manufacture of Thermal Transfer Sheet K. The image-forming layer of Thermal Transfer Sheet M obtained had a layer thickness of 0.38 μm.

[Composition of Magenta Pigment Dispersion Mother Solution]

Magenta Pigment Composition 1:

| | |
|---|---|
| Polyvinyl butyral (“DENKA BUTYRAL | 7.1 parts |
| #2000-L”, produced by Electrochemical | |
| Industry Co., Ltd., Vicut softening | |
| point: 57° C.) | |
| Pigment Red 57:1 (C.I. No. 15850:1) | 15.0 parts |
| (“Symuler Brilliant Carmine 6B-229”, | |
| produced by Dainippon Ink & Chemicals | |
| Inc.) | |
| Dispersion aid (“SOLSPERSE S-20000”, | 0.6 parts |
| produced by ICI) | |
| n-Propyl alcohol | 80.4 parts |

[Composition of Magenta Pigment Dispersion Mother Solution]

Magenta Pigment Composition 2:

| | |
|---|---|
| Polyvinyl butyral (“DENKA BUTYRAL | 12.6 parts |
| “2000-L”, produced by Electrochemical | |
| Industry Co., Ltd., Vicut softening | |
| point: 57° C.) | |
| Pigment Red 57:1 (C.I. No. 15850:1) | 15.0 parts |
| (“Linol Red 6B-4290G”, produced by | |
| Toyo Ink) | |
| Dispersion aid (“SOLSPERSE S-20000”, | 0.6 parts |
| produced by ICI) | |
| n-Propyl alcohol | 79.4 parts |

[Composition of Coating Solution for Magenta Image-Forming Layer]

| | |
|---|---|
| Magenta pigment dispersion mother | 163 parts |
| solution prepared above [Magenta | |
| Pigment Composition 1:Magenta | |
| Pigment Composition 2 = 95:5 (by | |
| parts)] | |
| Polyvinyl butyral (“DENKA BUTYRAL | 4.0 parts |
| “2000-L”, produced by Electrochemical | |
| Industry Co., Ltd., Vicut softening | |
| point: 57° C.) | |
| Wax-based compounds: | |
| (Stearic acid amide, “NEWTRON 2”, | 1.0 part |
| produced by Nippon Seika) | |
| (Behenic acid amide, “DIAMID BM”, | 1.0 part |
| produced by Nippon Kasei) | |
| (Lauric acid amide, “DIAMID Y”, | 1.0 part |
| produced by Nippon Kasei) | |
| (Palmitic acid amide, “DIAMID KP”, | 1.0 part |
| produced by Nippon Kasei) | |
| (Erucic acid amide, “DIAMID L-200”, | 1.0 part |
| produced by Nippon Kasei) | |
| (Oleic acid amide, “DIAMID O-200”, | 1.0 part |
| produced by Nippon Kasei) | |
| Nonionic surfactant (“CHEMISTAT 1100”, | 0.7 parts |
| produced by Sanyo Kasei) | |
| Rosin (“KE-311”, produced by Arakawa | 4.6 parts |
| Kagaku) (component: resin acid 80-97%, | |
| resin acid components: abietinic acid | |
| 30-40%, neoabitienic acid 10-20%, | |
| dihydroabitienic acid 14%, | |
| tetrahydroabitienic acid 14%) | |
| Pentaerythritol tetraacrylate (“NK | 2.5 parts |
| Ester A-TMMT”, produced by Shin | |
| Nakamura Kagaku K.K.) | |
| Surfactant (“Megafac F-176PF”, solid | 1.3 parts |
| content: 20%, produced by Dainippon | |
| Ink & Chemicals Inc.) | |
| n-Propyl alcohol | 848 parts |
| Methyl ethyl ketone | 246 parts |

The obtained image-forming layer had the following physical properties.

The surface hardness of the image-forming layer, which is preferably 10 g or more with a sapphire needle, was 200 g or more.

The Smooster value on the surface, which is preferably from 0.5 to 50 mmHg (≈0.0665 to 6.65 kPa) at 23° C. and 55% RH, was 3.5 mmHg (≈0.47 kPa).

The coefficient of static friction on the surface, which is preferably 0.2 or less, was 0.08.

The surface energy was 25 mJ/m², the contact angle to water was 98.8°, the reflection optical density was 1.51, the layer thickness was 0.38 μm and the OD/layer thickness was 3.97.

When the recording was performed using laser light having a light intensity of 1,000 W/mm² or more on the exposure surface at a linear velocity of 1 m/sec or more, the deformation percentage of the light-to-heat conversion layer was 160%.

Manufacture of Thermal Transfer Sheet C:

Thermal Transfer Sheet C was manufactured in the same manner as in the manufacture of Thermal Transfer Sheet K except for using the coating solution for cyan image-forming layer having a composition shown below in place of the coating solution for black image-forming layer in the manufacture of Thermal Transfer Sheet K. The image-forming layer of Thermal Transfer Sheet C obtained had a layer thickness of 0.45 μm.

[Composition of Cyan Pigment Dispersion Mother Solution]

Cyan Pigment Composition 1:

| | |
|---|---|
| Polyvinyl butyral (“Eslec B BL-SH”, | 12.6 parts |
| produced by Sekisui Chemical Co., | |
| Ltd.)) | |
| Pigment Blue 15:4 (C.I. No. 74160) | 15.0 parts |
| (“Cyanine Blue 700-10FG”, produced by | |
| Toyo Ink) | |
| Dispersion aid (“PW-36”, produced by | 0.8 parts |
| Kusumoto Kasei K.K.) | |
| n-Propyl alcohol | 110 parts |

[Composition of Cyan Pigment Dispersion Mother Solution]

Cyan Pigment Composition 2:

| | |
|---|---|
| Polyvinyl butyral (“Eslec B BL-SH”, | 12.6 parts |
| produced by Sekisui Chemical Co., | |
| Ltd.)) | |
| Pigment Blue 15 (C.I. No. 74160) | 15.0 parts |
| (“Linol Blue 7027”, produced by Toyo | |
| Ink) | |
| Dispersion aid (“PW-36”, produced by | 0.8 parts |
| Kusumoto Kasei K.K.) | |
| n-Propyl alcohol | 110 parts |

[Composition of Coating Solution for Cyan Image-Forming Layer]

| | |
|---|---|
| Cyan pigment dispersion mother | 118 parts |
| solution prepared above [Cyan Pigment | |
| Composition 1:Cyan Pigment | |
| Composition 2 = 90:10 (by parts)] | |
| Polyvinyl butyral (“Eslec B BL-SH”, | 5.2 parts |
| produced by Sekisui Chemical Co., | |
| Ltd.)) | |
| Wax-based compounds: | |
| (Stearic acid amide, “NEWTRON 2”, | 1.0 part |
| produced by Nippon Seika) | |
| (Behenic acid amide, “DIAMID BM”, | 1.0 part |
| produced by Nippon Kasei) | |
| (Lauric acid amide, “DIAMID Y”, | 1.0 part |
| produced by Nippon Kasei) | |
| (Palmitic acid amide, “DIAMID KP”, | 1.0 part |
| produced by Nippon Kasei) | |
| (Erucic acid amide, “DIAMID L-200”, | 1.0 part |
| produced by Nippon Kasei) | |
| (Oleic acid amide, “DIAMID O-200”, | 1.0 part |
| produced by Nippon Kasei) | |
| Rosin (“KE-311”, produced by Arakawa | 2.8 parts |
| Kagaku) (component: resin acid 80-97%, | |
| resin acid components: abietinic acid | |
| 30-40%, neoabitienic acid 10-20%, | |
| dihydroabitienic acid 14%, | |
| tetrahydroabitienic acid 14%) | |
| Pentaerythritol tetraacrylate (“NK | 1.7 parts |
| Ester A-TMMT”, produced by Shin | |
| Nakamura Kagaku K.K.) | |
| Surfactant (“Megafac F-176PF”, solid | 1.7 parts |
| content: 20%, produced by Dainippon | |
| Ink & Chemicals Inc.) | |
| n-Propyl alcohol | 890 parts |
| Methyl ethyl ketone | 247 parts |

The obtained image-forming layer had the following physical properties.

The surface hardness of the image-forming layer, which is preferably 10 g or more with a sapphire needle, was 200 g or more.

The Smooster value on the surface, which is preferably from 0.5 to 50 mmHg (≈0.0665 to 6.65 kPa) at 23° C. and 55% RH, was 7.0 mmHg (≈0.93 kPa).

The coefficient of static friction on the surface, which is preferably 0.2 or less, was 0.08.

The surface energy was 25 mJ/m², the contact angle to water was 98.8°, the reflection optical density was 1.59, the layer thickness was 0.45 μm and the OD/layer thickness was 3.03.

When the recording was performed using laser light having a light intensity of 1,000 W/mm² or more on the exposure surface at a linear velocity of 1 m/sec or more, the deformation percentage of the light-to-heat conversion layer was 165%.

Manufacture of Image-Receiving Sheet:

A coating solution for the cushion layer and a coating solution for the image-receiving layer each having the following composition were prepared.

1) Coating Solution for Cushion Layer

| | |
|---|---|
| Vinyl chloride-vinyl acetate copolymer | 20 parts |
| (main binder) (“MPR-TSL”, produced by | |
| Nisshin Kagaku) | |
| Plasticizer (“PARAPLEX G-40”, produced | 10 parts |
| by CP. HALL. COMPANY) | |
| Surfactant (“Megafac F-177”, produced | 0.5 parts |
| by Dainippon Ink & Chemicals Inc.) | |
| Antistatic agent (quaternary ammonium | 0.3 parts |
| salt) (“SAT-5 Supper (IC)”, produced | |
| by Nippon Junyaku K.K.) | |
| Methyl ethyl ketone | 60 parts |
| Toluene | 10 parts |
| N,N-Diznethylformamide | 3 parts |

2) Coating Solution for Image-Receiving Layer

| | |
|---|---|
| Polyvinyl butyral (“Eslec B BL-SH”, | 8 parts |
| produced by Sekisui Chemical Co., | |
| Ltd.) | |
| Surfactant (“Megafac F-177”, produced | 0.1 part |
| by Dainippon Ink & Chemicals Inc.) | |
| n-Propyl alcohol | 90 parts |

The coating solution for the formation of a cushion layer prepared above was coated on a white PET support (“LUMILER #130E58”, produced by Toray Industries, Inc., thickness: 130 μm) using a small-width coating machine and then, the coated layer was dried. Thereafter, the coating solution for the image-receiving layer was coated and dried. The amounts of coating solutions were controlled such that after the drying, the cushion layer had a thickness of about 20 μm and the image-receiving layer had a thickness of about 2 μm. The white PET support was a void-containing plastic support comprising a laminate (total thickness: 130 μm, specific gravity: 0.8) of a void-containing polyethylene terephthalate layer (thickness: 116 μm, porosity: 20%) and titanium oxide-containing polyethylene terephthalate layers (thickness: 7 μm, titanium oxide content: 2%) provided on both surfaces of the void-containing polyethylene terephthalate layer. The manufactured material was taken up into a roll form and stored at room temperature for 1 week. Thereafter, this material was used for the following image recording by laser light and also subjected to the measurements of the peeling strength and the contact angle to water.

The obtained image-receiving layer had the following physical properties.

The surface roughness Ra, which is preferably from 0.4 to 0.01 μm, was 0.05 μm.

The waviness on the surface of the image-receiving layer, which is preferably 2 μm or less, was 1.6 μm.

The Smooster value on the surface of the image-receiving layer, which is preferably from 0.5 to 50 mmHg (≈0.0665 to 6.65 kPa) at 23° C. and 55% RH, was 0.8 mmHg (≈0.11 kPa).

The coefficient of static friction on the surface of the image-receiving layer, which is preferably 0.8 or less, was 0.37.

Formation of Transfer Image:

The image-receiving sheet (56 cm×79 cm) prepared above was wound around a 38 cm-diameter rotary drum having punched thereon vacuum section holes (plane density: 1 hole per area of 3 cm×8 cm) having a diameter of 1 mm and vacuum-adsorbed. Subsequently, Thermal Transfer Sheet K (black) prepared above, which was cut into 61 cm×84 cm, was superposed to uniformly protrude from the image-receiving sheet and adhesion-laminated while squeezing by a squeeze roller to allow air to be suctioned through the section holes. The decompression degree was −150 mmHg (≈81.13 kPa) to 1 atm. in the state where the section holes were closed. The drum was rotated and on the laminate surface on the drum, semiconductor laser light at a wavelength of 808 nm were irradiated from the outside and converged to form a spot of 7 μm on the surface of the light-to-heat conversion layer. While moving the light in the direction (sub-scanning) right-angled to the rotating direction (main scanning direction) of the rotary drum, a laser image (image and line) was recorded on the laminate. The laser irradiation conditions were as follows. The laser beam used in this Example was a laser beam having a multibeam two-dimensional arrangement comprising parallelograms forming 5 lines in the main scanning direction and 3 lines in the sub-scanning direction.

| | |
|---|---|
| Laser power: | 110 mW |
| Rotation number of drum | 500 rpm |
| Sub-scanning pitch | 6.35 μm |

Humidity and temperature in environment:

Three conditions of 18° C. and 30%, 23° C. and 50%, and 26° C. and 65%.

The diameter of the exposure drum, which is preferably 360 mm or more, was 380 mm.

The image size was 515 mm×728 mm and the resolution was 2,600 dpi.

After the completion of laser recording, the laminate was removed from the drum and Thermal Transfer Sheet K was manually peeled off from the image-receiving sheet, as a result, it was confirmed that only the image-forming layer of Thermal Transfer Sheet K in the region irradiated with light was transferred to the image-receiving sheet from Thermal Transfer Sheet K.

In the same manner as above, an image was transferred to the image-receiving sheet from each thermal transfer sheet of Thermal Transfer Sheet Y, Thermal Transfer Sheet M and Thermal Transfer Sheet C. The four-color image thus transferred was further transferred to recording paper to form a multicolor image. As a result, a multicolor image having good image quality and stable transfer density could be formed under different temperature and humidity conditions even when laser recording with high energy was performed using laser light having a multibeam two-dimensional arrangement.

The transfer to printing paper was performed using a thermal transfer device in which the coefficient of dynamic friction of the construction material of the insertion table to polyethylene terephthalate was 0.1 to 0.7 and the transportation speed was 15 to 50 mm/sec. In the thermal transfer device, the Vickers hardness of the construction material of the heat roll, which is preferably from 10 to 100, was 70.

In all of three environmental temperature and humidity conditions, a good image was obtained.

Also, the resolution of the line image area of the cyanine transfer image transferred to printing paper was evaluated and the results obtained are shown in Table 1.

### Example 1-2

An image-receiving sheet was manufactured in the same manner as in Example 1-1 except that the coating solution for the image-receiving layer of Example 1-1 was changed to the following composition.

| | |
|---|---|
| Polyvinyl butyral (“Eslec B BL-SH”, | 8 parts |
| produced by Sekisui Chemical Co., | |
| Ltd.) | |
| Antistatic agent (“SANSTAT 2012A”, | 0.7 parts |
| produced by Sanyo Kasei Kogyo K.K.) | |
| Surfactant (“Megafac F-177”, produced | 0.1 part |
| by Dainippon Ink & Chemicals Inc.) | |
| n-Propyl alcohol | 20 parts |
| Methanol | 20 parts |
| 1-Methoxy-2-propanol | 50 parts |

### Example 1-3

An image-receiving sheet was manufactured in the same manner as in Example 1-1 except that the coating solution for the image-receiving layer of Example 1-1 was changed to the following composition.

Coating Solution for Image-Forming Layer:

| | |
|---|---|
| Acrylic resin latex (IODOSOL A5801, | 2 parts |
| produced by Kanebo NSC) | |
| Surfactant (“Megafac F-177”, produced | 1.2 parts |
| by Dainippon Ink & Chemicals Inc.) | |
| Dimethyl ketone | 80 parts |
| Dimethylformamide | 20 parts |

### Example 1-4

An image-receiving sheet was manufactured in the same manner as in Example 1-1 except that in the coating solution for the image-receiving layer in Example 1-3, the amount of the surfactant was changed to 4.8 parts.

### Example 1-5

An image-receiving sheet was manufactured in the same manner as in Example 1-1 except that in the coating solution for the image-receiving layer of Example 1-1, 10 parts of an antistatic agent (“SANSTAT 2012A”, produced by Sanyo Kasei Kogyo K.K.) was added.

### Example 1-6

An image-receiving sheet was manufactured in the same manner as in Example 1-1 except that the coating solution for the image-receiving layer of Example 1-1 was changed to the following composition.

Coating Solution for Image-Forming Layer:

| | |
|---|---|
| Acrylic resin latex (IODOSOL A5801, | 30.4 parts |
| produced by Kanebo NSC) | |
| 25 Mass % water dispersion of 2 μm PMMA | 1.9 parts |
| matting agent | |
| Fluorine-containing resin (Sumirez | 5.7 parts |
| Resin FP-150) | |
| Water | 60 parts |
| Isopropyl alcohol | 2 parts |

### Comparative Example 1-1

An image-receiving sheet was manufactured in the same manner as in Example 1-1 except that in the coating solution for the image-receiving layer of Example 1-1, 8 parts of an antistatic agent (“SANSTAT 2012A”, produced by Sanyo Kasei Kogyo K.K.) was added and the sheet was stored under high humidity conditions (25° C., 75% RH).

The image-receiving sheets obtained in Examples 1-2 to 1-5 and Comparative Examples 1-1 and 1-2 each was measured on the peeling strength and the contact angle in the same manner as in Example 1-1. Furthermore, the resolution (fine line fixing) was evaluated in the same manner as in Example 1-1. The results are shown in Table 1.

Fine Line Fixing:

TABLE 1

| | Peeling | | |
|---|---|---|---|
| | Strength | Contact Angle | Fine Line |
| Sample | (mN/cm) | (°) | Fixing |
| Example 1-1 | 4472 | 85 | ⊚ |
| Example 1-2 | 3546 | 61 | ⊚ |
| Example 1-3 | 2350 | 43 | ⊚ |
| Example 1-4 | 1083 | 22 | ◯ |
| Example 1-5 | 830 | 10 | ◯ |
| Example 1-6 | 820 | 7 | Δ |
| Comparative | 710 | 6 | X |
| Example 1-1 | | | |

⊚: No thinning or transfer failure of line image after recording was present.
◯: Slight thinning of line image after recording was present.
Δ: Thinning of line image or partial transfer failure after recording was present.
X: Serious thinning of line image or transfer failure of line image itself after recording was present.

It is seen from Table 1 that the image-receiving sheets of Examples having a peeling strength within the scope of the present invention are improved in the fine line fixing as compared with the image-receiving sheets of Comparative Examples out of the scope of the present invention.

### Example 2-1

Thermal Transfer Sheets K, Y, M and C same as those in Example 1-1 were used as the thermal transfer sheets of an image-forming material.

Manufacture of Image-Receiving Sheet:

A coating solution for the cushion layer and a coating solution for the image-receiving layer each having the following composition were prepared.

1) Coating Solution for Cushion Layer

| | |
|---|---|
| Vinyl chloride-vinyl acetate copolymer | 20 parts |
| (main binder) (“MPR-TSL”, produced by | |
| Nisshin Kagaku) | |
| Plasticizer (“PARAPLEX G-40”, produced | 10 parts |
| by CP. HALL. COMPANY) | |
| Surfactant (fluorine-containing | 0.5 parts |
| surfactant, coating aid) (“Megafac F-177”, | |
| produced by Dainippon Ink & | |
| Chemicals Inc.) | |
| Antistatic agent (quaternary ammonium | 0.3 parts |
| salt) (“SAT-5 Supper (IC)”, produced | |
| by Nippon Junyaku K.K.) | |
| Methyl ethyl ketone | 60 parts |
| Toluene | 10 parts |
| N,N-Dimethylformamide | 3 parts |

2) Coating Solution for Image-Receiving Layer

| | |
|---|---|
| Polyvinyl butyral (“Eslec B BL-SH”, | 8 parts |
| produced by Sekisui Chemical Co., | |
| Ltd.) | |
| Antistatic agent (“SANSTAT 2012A”, | 1.4 parts |
| produced by Sanyo Kasei Kogyo K.K.) | |
| Surfactant (“Megafac F-177”, produced | 0.2 part |
| by Dainippon Ink & Chemicals Inc.) | |
| n-Propyl alcohol | 20 parts |
| Methanol | 20 parts |
| 1-Methoxy-2-propanol | 50 parts |

The coating solution for the formation of a cushion layer prepared above was coated on a white PET support (“LUMILER #130E58”, produced by Toray Industries, Inc., thickness: 130 μm) using a small-width coating machine and then, the coated layer was dried. Thereafter, the coating solution for the image-receiving layer was coated and dried. The amounts of coating solutions were controlled such that after the drying, the cushion layer had a thickness of about 20 μm and the image-receiving layer had a thickness of about 2 μm. The white PET support was a void-containing plastic support comprising a laminate (total thickness: 130 μm, specific gravity: 0.8) of a void-containing polyethylene terephthalate layer (thickness: 116 μm, porosity: 20%) and titanium oxide-containing polyethylene terephthalate layers (thickness: 7 μm, titanium oxide content: 2%) provided on both surfaces of the void-containing polyethylene terephthalate layer. The manufactured material was taken up into a roll form and stored at room temperature for 1 week. Thereafter, this material was used for the following image recording by laser light and also subjected to the measurements of the peeling strength and Ra.

The obtained image-receiving layer had the following physical properties.

The surface roughness Ra, which is preferably from 0.4 to 0.01 μm, was 0.02 μm.

The waviness on the surface of the image-receiving layer, which is preferably 2 μm or less, was 1.2 μm.

The Smooster value on the surface of the image-receiving layer, which is preferably from 0.5 to 50 mmHg (≈0.0665 to 6.65 kPa) at 23° C. and 55% RH, was 0.5 mmHg (≈0.0665 kPa).

The coefficient of static friction on the surface of the image-receiving layer, which is preferably 0.8 or less, was 0.33.

Formation of Transfer Image:

The image-receiving sheet (56 cm×79 cm) prepared above was wound around a 38 cm-diameter rotary drum having punched thereon vacuum section holes (plane density: 1 hole per area of 3 cm×8 cm) having a diameter of 1 mm and vacuum-adsorbed. Subsequently, Thermal Transfer Sheet K (black) prepared above, which was cut into 61 cm×84 cm, was superposed to uniformly protrude from the image-receiving sheet and adhesion-laminated while squeezing by a squeeze roller to allow air to be suctioned through the section holes. The decompression degree was −150 mmHg (≈81.13 kPa) to 1 atm. in the state where the section holes were closed. The drum was rotated and on the laminate surface on the drum, semiconductor laser light at a wavelength of 808 nm were irradiated from the outside and converged to form a spot of 7 μm on the surface of the light-to-heat conversion layer. While moving the light in the direction (sub-scanning) right-angled to the rotating direction (main scanning direction) of the rotary drum, a laser image (image and line) was recorded on the laminate. The laser irradiation conditions were as follows. The laser beam used in this Example was a laser beam having a multibeam two-dimensional arrangement comprising parallelograms forming 5 lines in the main scanning direction and 3 lines in the sub-scanning direction.

| | |
|---|---|
| Laser power: | 110 mW |
| Rotation number of drum | 500 rpm |
| Sub-scanning pitch | 6.35 μm |

Humidity and temperature in environment:

Three conditions of 18° C. and 30%, 23° C. and 50%, and 26° C. and 65%.

The diameter of the exposure drum, which is preferably 360 mm or more, was 380 mm.

The image size was 515 mm×728 mm and the resolution was 2,600 dpi.

After the completion of laser recording, the laminate was removed from the drum and Thermal Transfer Sheet K was manually peeled off from the image-receiving sheet, as a result, it was confirmed that only the image-forming layer of Thermal Transfer Sheet K in the region irradiated with light was transferred to the image-receiving sheet from Thermal Transfer Sheet K.

In the same manner as above, an image was transferred to the image-receiving sheet from each thermal transfer sheet of Thermal Transfer Sheet Y, Thermal Transfer Sheet M and Thermal Transfer Sheet C. The four-color image thus transferred was further transferred to recording paper to form a multicolor image. As a result, a multicolor image having good image quality and stable transfer density could be formed under different temperature and humidity conditions even when laser recording with high energy was performed using laser light having a multibeam two-dimensional arrangement.

The transfer to printing paper was performed using a thermal transfer device in which the coefficient of dynamic friction of the construction material of the insertion table to polyethylene terephthalate was 0.1 to 0.7 and the transportation speed was 15 to 50 mm/sec. In the thermal transfer device, the Vickers hardness of the construction material of the heat roll, which is preferably from 10 to 100, was 70.

In all of three environmental temperature and humidity conditions, a good image was obtained.

Also, the resolution of the line image area of the cyanine transfer image transferred to printing paper was evaluated and the results obtained are shown in Table 1.

### Example 2-2

An image-receiving sheet was manufactured in the same manner as in Example 2-1 except that in the coating solution for the image-receiving layer of Example 2-1, the amounts of surfactant and antistatic agent were changed to 0.1 part and 0.7 parts, respectively.

### Example 2-3

An image-receiving sheet was manufactured in the same manner as in Example 2-1 except that in the coating solution for the image-receiving layer of Example 2-1, the amounts of surfactant and antistatic agent were changed to 0.4 parts and 2.8 parts, respectively.

### Example 2-4

An image-receiving sheet was manufactured in the same manner as in Example 2-1 except that the coating solution for the image-receiving layer of Example 2-1 was changed to the following composition.

Coating Solution for Image-Forming Layer

| | |
|---|---|
| Acrylic resin latex (IODOSOL A5801, | 30.4 parts |
| produced by Kanebo NSC) | |
| 25 Mass % water dispersion of 2 μm PMMA | 1.9 parts |
| matting agent | |
| Fluorine-containing resin (Sumirez | 5.7 parts |
| Resin FP-150) | |
| Water | 60 parts |
| IPA | 2 parts |

### Reference Example 2-1

An image-receiving sheet was manufactured in the same manner as in Example 2-1 except that in the coating solution for the image-receiving layer of Example 2-1, the amounts of surfactant and antistatic agent were changed to 1.0 part and 7.0 parts, respectively. The results are shown in Table 2.

Fine Line Fixing:

TABLE 2

| | Peeling | Center Line | |
|---|---|---|---|
| | Strength | Average Surface | Fine Line |
| Sample | (mN/cm) | Roughness (Ra) , μ | Fixing |
| Example 2-1 | 1714 | 0.05 | ⊚ |
| Example 2-2 | 2300 | 0.024 | ⊚ |
| Example 2-3 | 1127 | 0.03 | ◯ |
| Example 2-4 | 820 | 0.025 | Δ |
| Reference | 600 | 0.05 | X |
| Example 2-1 | | | |

⊚: No thinning or transfer failure of line image after recording was present.
◯: Slight thinning of line image after recording was present.
Δ: Thinning of line image or partial transfer failure after recording was present.
X: Serious thinning of line image or transfer failure of line image itself after recording was present.

It is seen from Table 2 that the image-receiving sheets of Examples are improved in the fine line fixing as compared with the image-receiving sheets of Reference Examples.

### Example 3-1

Thermal Transfer Sheets K, Y, M and C same as those in Example 1-1 were used as the thermal transfer sheets of an image-forming material.

Manufacture of Image-Receiving Sheet:

A coating solution for the cushion layer and a coating solution for the image-receiving layer each having the following composition were prepared.

1) Coating Solution for Cushion Layer

| | |
|---|---|
| Vinyl chloride-vinyl acetate copolymer | 20 parts |
| (main binder) (“MPR-TSL”, produced by | |
| Nisshin Kagaku) | |
| Plasticizer (“PARAPLEX G-40”, produced | 10 parts |
| by CP. HALL. COMPANY) | |
| Surfactant (fluorine-containing | 0.5 parts |
| surfactant, coating aid) (“Megafac F-177”, | |
| produced by Dainippon Ink & | |
| Chemicals Inc.) | |
| Antistatic agent (quaternary ammonium | 0.3 parts |
| salt) (“SAT-5 Supper (IC)”, produced | |
| by Nippon Junyaku K.K.) | |
| Methyl ethyl ketone | 60 parts |
| Toluene | 10 parts |
| N,N-Dimethylformamide | 3 parts |

2) Coating Solution for Image-Receiving Layer

| | |
|---|---|
| Polyvinyl butyral (“Eslec B BL-SH”, | 8 parts |
| produced by Sekisui Chemical Co., | |
| Ltd.) | |
| Antistatic agent (“SANSTAT 2012A”, | 0.7 parts |
| produced by Sanyo Kasei Kogyo K.K.) | |
| Surfactant (“Megafac F-177”, produced | 0.1 part |
| by Dainippon Ink & Chemicals Inc.) | |
| n-Propyl alcohol | 20 parts |
| Methanol | 20 parts |
| 1-Methoxy-2-propanol | 50 parts |

The coating solution for the formation of a cushion layer prepared above was coated on a white PET support (“LUMILER #130E58”, produced by Toray Industries, Inc., thickness: 130 μm) using a small-width coating machine and then, the coated layer was dried. Thereafter, the coating solution for the image-receiving layer was coated and dried. The amounts of coating solutions were controlled such that after the drying, the cushion layer had a thickness of about 20 μm and the image-receiving layer had a thickness of about 2 μm. The white PET support was a void-containing plastic support comprising a laminate (total thickness: 130 μm, specific gravity: 0.8) of a void-containing polyethylene terephthalate layer (thickness: 116 μm, porosity: 20%) and titanium oxide-containing polyethylene terephthalate layers (thickness: 7 μm, titanium oxide content: 2%) provided on both surfaces of the void-containing polyethylene terephthalate layer. The manufactured material was taken up into a roll form and stored at room temperature for 1 week. Thereafter, this material was used for the following image recording by laser light.

The obtained image-receiving layer had the following physical properties.

The surface roughness Ra, which is preferably from 0.4 to 0.01 μm, was 0.02 μm.

The waviness on the surface of the image-receiving layer, which is preferably 2 μm or less, was 1.2 μm.

The Smooster value on the surface of the image-receiving layer, which is preferably from 0.5 to 50 mmHg (≈0.0665 to 6.65 kPa) at 23° C. and 55% RH, was 0.8 mmHg (≈0.11 kPa).

The coefficient of static friction on the surface of the image-receiving layer, which is preferably 0.8 or less, was 0.37.

The surface energy on the surface of the image-receiving layer was 29 mJ/m² and the contact angle to water was 85.0°.

Formation of Transfer Image:

A transfer image was obtained on printing paper using the system shown in FIG. 4 as the image formation system, Luxel FINALPROOF 5600 as the recording device, the image formation sequence in the system of the present invention, and the printing paper transfer method for use in the system of the present invention.

The image-receiving sheet (56 cm×79 cm) prepared above was wound around a 38 cm-diameter rotary drum having punched thereon vacuum section holes (plane density: 1 hole per area of 3 cm×8 cm) having a diameter of 1 mm and vacuum-adsorbed. Subsequently, Thermal Transfer Sheet K (black) prepared above, which was cut into 61 cm×84 cm, was superposed to uniformly protrude from the image-receiving sheet and adhesion-laminated while squeezing by a squeeze roller to allow air to be suctioned through the section holes. The decompression degree was −150 mmHg (≈81.13 kPa) to 1 atm. in the state where the section holes were closed. The drum was rotated and on the laminate surface on the drum, semiconductor laser light at a wavelength of 808 nm were irradiated from the outside and converged to form a spot of 7 μm on the surface of the light-to-heat conversion layer. While moving the light in the direction (sub-scanning) right-angled to the rotating direction (main scanning direction) of the rotary drum, a laser image (image and line) was recorded on the laminate. The laser irradiation conditions were as follows. The laser beam used in this Example was a laser beam having a multibeam two-dimensional arrangement comprising parallelograms forming 5 lines in the main scanning direction and 3 lines in the sub-scanning direction.

| | |
|---|---|
| Laser power: | 110 mW |
| Rotation number of drum | 500 rpm |
| Sub-scanning pitch | 6.35 μm |

Humidity and temperature in environment:

Three conditions of 18° C. and 30%, 23° C. and 50%, and 26° C. and 65%.

The diameter of the exposure drum, which is preferably 360 mm or more, was 380 mm.

The image size was 515 mm×728 mm and the resolution was 2,600 dpi.

After the completion of laser recording, the laminate was removed from the drum and Thermal Transfer Sheet K was manually peeled off from the image-receiving sheet, as a result, it was confirmed that only the image-forming layer of Thermal Transfer Sheet K in the region irradiated with light was transferred to the image-receiving sheet from Thermal Transfer Sheet K.

In the same manner as above, an image was transferred to the image-receiving sheet from each thermal transfer sheet of Thermal Transfer Sheet Y, Thermal Transfer Sheet M and Thermal Transfer Sheet C. The four-color image thus transferred was further transferred to recording paper to form a multicolor image. As a result, a multicolor image having good image quality and stable transfer density could be formed under different temperature and humidity conditions even when laser recording with high energy was performed using laser light having a multibeam two-dimensional arrangement.

The transfer to printing paper was performed using a thermal transfer device in which the coefficient of dynamic friction of the construction material of the insertion table to polyethylene terephthalate was 0.1 to 0.7 and the transportation speed was 15 to 50 mm/sec. In the thermal transfer device, the Vickers hardness of the construction material of the heat roll, which is preferably from 10 to 100, was 70.

In all of three environmental temperature and humidity conditions, a good image was obtained.

The reflection optical density was measured on an image transferred to printing paper TOKUHISHI Art paper with respect to Y, M, C and K colors in Y, M, C and K modes, respectively, using a densitometer X-rite 938 (manufactured by X-rite).

The reflection optical density of each color and the reflection optical density/layer thickness of image-forming layer are shown in Table 3.

TABLE 3

| | Optical | Optical Density/Layer Thickness |
|---|---|---|
| | Density | of Image-Forming Layer |
| Color Y | 1.01 | 2.40 |
| Color M | 1.51 | 3.97 |
| Color C | 1.59 | 3.53 |
| Color K | 1.82 | 3.03 |

### Example 3-2

A material was manufactured in the same manner as in Example 3-1 except that in place of the image-receiving sheet used in Example 3-1, the cushion layer was dried at 120° C. for 2 minutes and the image-receiving layer was dried at 150° C. for 2 minutes. Using this material, a transfer image was formed in the same process.

### Example 3-3

A material was manufactured in the same manner as in Example 3-1 except that in place of the image-receiving sheet used in Example 3-1, the cushion layer was dried at 110° C. for 1 minute and the image-receiving layer was dried at 140° C. for 1 minute. Using this material, a transfer image was formed in the same process.

### Reference Example 3-1

A material was manufactured in the same manner as in Example 3-1 except that in place of the image-receiving sheet used in Example 3-1, the cushion layer was dried at 130° C. for 5 minutes and the image-receiving layer was dried at 160° C. for 5 minutes. Using this material, a transfer image was formed through the same process.

### Reference Example 3-2

A material was manufactured in the same manner as in Example 3-1 except that in place of the image-receiving sheet used in Example 3-1, the cushion layer was dried at 100° C. for 1 minute and the image-receiving layer was dried at 130° C. for 1 minute. Using this material, a transfer image was formed through the same process.

The residual solvent amount (calculated by (formula 1)) of each of the image-receiving sheets of Examples 3-1 to 3-3 and Reference Examples 2-1 and 2-2 is shown in Table 4.

The obtained transfer image was evaluated as follows. The evaluation results are shown in Table 4.

Evaluation of Black Image Quality

The solid part and the line image part of the transfer image obtained using Thermal Transfer Sheet K were observed through an optical microscope. The image quality was evaluated with an eye according to the following criteria.

Line Image Part:

◯: The edge of line image was sharp, revealing good resolution.

Δ: The edge of line image was indented and cutting of line was partially generated.

X: Cutting of line was thoroughly generated.

Evaluation of Printing Paper Transferability

A full surface 50% halftone dot image obtained using the image-receiving sheet and Thermal Transfer Sheet K manufactured above was laminated on TOKUHISHI Art (157 g/m², produced by Mitsubishi Paper Mills, Ltd.) through the printing paper transfer sequence according to the present invention. After cooling to room temperature, the image-receiving sheet placed upward was peeled off from one corner at a constant speed. The weight at the peeling and the presence or absence of the paper tearing were evaluated.

TABLE 4

| | Construction | | | |
|---|---|---|---|---|
| | Residual | Evaluation | | |
| | Solvent | | | Printing |
| | Amount of | | Printing | Paper |
| | Image- | Line | Paper | Transferability |
| | Receiving | Image | Transferability | (paper |
| | Sheet (μ1/m²) | Quality | (weight) | tearing) |
| Example 3-1 | 42 | ⊚ | ◯ | ◯ |
| Example 3-2 | 15 | ◯ | ◯ | ◯ |
| Example 3-3 | 69 | ⊚ | Δ | ◯ |
| Reference | 3 | X | ◯ | ◯ |
| Example 3-1 | | | | |
| Reference | 109 | ⊚ | X | X |
| Example 3-2 | | | | |

Weight on Peeling:
◯: Lightly and smoothly peeled off.
Δ: Slightly heavily but smoothly peeled off.
X: More heavily peeled off or unless cared, the peeling stopped on the way.
Paper Tearing:
◯: Transferred in good state without paper tearing.
Δ: On careful observation, slight paper tearing was generated.
X: At a glance, noticeable paper tearing was generated.

### Example 4-1

Thermal Transfer Sheets K, Y, M and C same as those in Example 1-1 were used as the thermal transfer sheets of an image-forming material.

Manufacture of Image-Receiving Sheet:

A coating solution for the cushion layer and a coating solution for the image-receiving layer each having the following composition were prepared.

1) Coating Solution for Cushion Layer

| | |
|---|---|
| Vinyl chloride-vinyl acetate copolymer | 20 parts |
| (main binder) (“MPR-TSL”, produced by | |
| Nisshin Kagaku) | |
| Plasticizer (“PARAPLEX G-40”, produced | 10 parts |
| by CP. HALL. COMPANY) | |
| Surfactant (fluorine-containing | 0.5 parts |
| surfactant, coating aid) (“Megafac F-177”, | |
| produced by Dainippon Ink & | |
| Chemicals Inc.) | |
| Antistatic agent (quaternary ammonium | 0.3 parts |
| salt) (“SAT-5 Supper (IC)”, produced | |
| by Nippon Junyaku K.K.) | |
| Methyl ethyl ketone | 60 parts |
| Toluene | 10 parts |
| N,N-Dimethylformamide | 3 parts |

2) Coating Solution for Image-Receiving Layer

| | |
|---|---|
| Polyvinyl butyral (“DENKA BUTYRAL | 8 parts |
| #2000-L”, produced by Electrochemical | |
| Industry Co., Ltd.) | |
| Antistatic agent (“SANSTAT 2012A”, | 0.7 parts |
| produced by Sanyo Kasei Kogyo K.K.) | |
| Surfactant (“Megafac F-177”, produced | 0.1 part |
| by Dainippon Ink & Chemicals Inc.) | |
| n-Propyl alcohol | 20 parts |
| Methanol | 20 parts |
| 1-Methoxy-2-propanol | 50 parts |

The coating solution for the formation of a cushion layer prepared above was coated on a white PET support (“LUMILER #130E58”, produced by Toray Industries, Inc., thickness: 130 μm) using a small-width coating machine and then, the coated layer was dried. Thereafter, the coating solution for the image-receiving layer was coated and dried. The amounts of coating solutions were controlled such that after the drying, the cushion layer had a thickness of about 20 μm and the image-receiving layer had a thickness of about 2 μm. The white PET support was a void-containing plastic support comprising a laminate (total thickness: 130 μm, specific gravity: 0.8) of a void-containing polyethylene terephthalate layer (thickness: 116 μm, porosity: 20%) and titanium oxide-containing polyethylene terephthalate layers (thickness: 7 μm, titanium oxide content: 2%) provided on both surfaces of the void-containing polyethylene terephthalate layer. The manufactured material was taken up into a roll form and stored at room temperature for 1 week. Thereafter, this material was used for the following image recording by laser light.

The obtained image-receiving layer had the following physical properties.

The surface roughness Ra, which is preferably from 0.4 to 0.01 μm, was 0.02 μm.

The waviness on the surface of the image-receiving layer, which is preferably 2 μm or less, was 0.5 μm.

The Smooster value on the surface of the image-receiving layer, which is preferably from 0.5 to 50 mmHg (≈0.0665 to 6.65 kPa) at 23° C. and 55% RH, was 0.8 mmHg (≈0.11 kPa).

The coefficient of static friction on the surface of the image-receiving layer, which is preferably 0.8 or less, was 0.31.

Formation of Transfer Image:

The image-receiving sheet (56 cm×79 cm) prepared above was wound around a 38 cm-diameter rotary drum having punched thereon vacuum section holes (plane density: 1 hole per area of 3 cm×8 cm) having a diameter of 1 mm and vacuum-adsorbed. Subsequently, Thermal Transfer Sheet K (black) prepared above, which was cut into 61 cm×84 cm, was superposed to uniformly protrude from the image-receiving sheet and adhesion-laminated while squeezing by a squeeze roller to allow air to be suctioned through the section holes. The decompression degree was −150 mmHg (≈81.13 kPa) to 1 atm. in the state where the section holes were closed. The drum was rotated and on the laminate surface on the drum, semiconductor laser light at a wavelength of 808 nm were irradiated from the outside and converged to form a spot of 7 μm on the surface of the light-to-heat conversion layer. While moving the light in the direction (sub-scanning) right-angled to the rotating direction (main scanning direction) of the rotary drum, a laser image (image and line) was recorded on the laminate. The laser irradiation conditions were as follows. The laser beam used in this Example was a laser beam having a multibeam two-dimensional arrangement comprising parallelograms forming 5 lines in the main scanning direction and 3 lines in the sub-scanning direction.

| | |
|---|---|
| Laser power: | 110 mW |
| Rotation number of drum | 500 rpm |
| Sub-scanning pitch | 6.35 μm |

Humidity and temperature in environment:

Three conditions of 18° C. and 30%, 23° C. and 50%, and 26° C. and 65%.

The diameter of the exposure drum, which is preferably 360 mm or more, was 380 mm.

The image size was 515 mm×728 mm and the resolution was 2,600 dpi.

After the completion of laser recording, the laminate was removed from the drum and Thermal Transfer Sheet K was manually peeled off from the image-receiving sheet, as a result, it was confirmed that only the image-forming layer of Thermal Transfer Sheet K in the region irradiated with light was transferred to the image-receiving sheet from Thermal Transfer Sheet K.

In the same manner as above, an image was transferred to the image-receiving sheet from each thermal transfer sheet of Thermal Transfer Sheet Y, Thermal Transfer Sheet M and Thermal Transfer Sheet C. The four-color image thus transferred was further transferred to recording paper to form a multicolor image. As a result, a multicolor image having good image quality and stable transfer density could be formed in any environmental conditions. The printing paper used was rough paper (Green DAIO).

The transfer to printing paper was performed using a thermal transfer device in which the coefficient of dynamic friction of the construction material of the insertion table to polyethylene terephthalate was 0.1 to 0.7 and the transportation speed was 15 to 50 mm/sec. In the thermal transfer device, the Vickers hardness of the construction material of the heat roll, which is preferably from 10 to 100, was 70. The roll temperature in the processing was 130° C.

In all of three environmental temperature and humidity conditions, a good image was obtained.

### Example 4-2

A multicolor image was formed in the same manner as in Example 4-1 except that the image-receiving layer was formed by changing the coating solution for the image-receiving layer of Example 4-1 to the following composition. Then, the image was transferred to printing paper.

More specifically, a multicolor image was formed in the same manner as in Example 4-1 except that a coating film (1.3 μm) was formed on the cushion layer of the image-receiving sheet of Example 4-1 by using Coating Solution 1 having the following composition:

| | |
|---|---|
| Ethyl cellulose (ETHOCEL, produced by | 10 parts |
| Dow Chemical) | |
| Isopropyl alcohol (IPA) | 90 parts |

and a coated film (1.2 μm) was formed using Coating Solution 2 having the following composition:

| | |
|---|---|
| Acrylic resin latex (IODOSOL A5801, | 30.4 parts |
| produced by Kanebo NSC) | |
| 25 Mass % water dispersion of 2 μm PMMA | 1.9 parts |
| matting agent | |
| Fluorine-containing resin (Sumirez | 5.7 parts |
| Resin FP-150) | |
| Water | 60 parts |
| IPA | 2 parts |

The sample for the measurements of Tg and elongation at break was measured after peeling the film from the support and then, in the case of Tg, packing it in a stainless steel cell or in the case of elongation at break, forming the film into strips of 5×70 mm.

### Reference Example 4-1

A multicolor image was formed in the same manner as in Example 4-1 except that the coating solution for the image-receiving layer of Example 4-1 was changed to the following composition. Then, the image was transferred to printing paper.

Coating Solution for Image-Receiving Layer:

| | |
|---|---|
| Acrylic resin latex (IODOSOL A5801, | 30.4 parts |
| produced by Kanebo NSC) | |
| 25 Mass % water dispersion of 2 μm PMMA | 1.9 parts |
| matting agent | |
| Fluorine-containing resin (Sumirez | 5.7 parts |
| Resin FP-150) | |
| Water | 60 parts |
| IPA | 2 parts |

### Reference Example 4-2

A multicolor image was formed in the same manner as in Example 4-1 except that the acrylic resin latex in the coating solution for the image-receiving layer of Reference Example 4-1 was changed to IODOSOL AD79B. Then, the image was transferred to printing paper.

For the measurements of Tg and elongation at break of the acrylic resin latex, the sample obtained by coating the coating solution on PET or Teflon support to a thickness of about 10 μm was, in the case of Tg, packed in a stainless steel cell or in the case of elongation at break, formed into strips of 5×70 mm.

The image transferred was evaluated on the printing paper transferability on rough paper and on the lifting of image. The results are shown in Table 5.

The lifting of image was evaluated as follows.

TABLE 5

| | | | | Printing | |
|---|---|---|---|---|---|
| | Polymer or | Tg | Elongation at | Paper | Lifting |
| | its | (25° C., | break | Transferability | of |
| Sample | Composition | 50% RH) | (%) | (rough paper) | Image |
| Example 4-1 | polyvinyl | 56 | 1.7 | transferred | ◯ |
| | butyral | | | | |
| Example 4-2 | acrylic resin | 44 | 130 | transferred | Δ |
| | latex/ethyl cellulose | | | | |
| Reference | acrylic resin | 1 | 183 | transferred | X |
| Example 4-1 | latex (A5801) | | | | |
| Reference | acrylic resin | 5 | 289 | transferred | X |
| Example 4-2 | latex (AD79B) | | | | |

◯: No gap was confirmed with an eye between printing paper and image-receiving layer.
Δ: A fine gap (0.5 mm or less) was confirmed with an eye between printing paper and image-receiving layer.
X: A gap in excess of 0.5 mm was confirmed with an eye between printing paper and image-receiving layer.

It is seen from Table 5 that the image-receiving sheet of Examples 4-1 and 4-2 can be transferred to rough paper and as compared with Reference Examples, prevented from lifting of image and favored with excellent scratch resistance.

According to the present invention, a contract proof capable of coping with filmless processing in the CTP time and taking the place of proof printing or analogue color proof can be provided. This proof can realize color reproduction agreeing with the printed matter or analogue color proof for acquiring the approval from clients. Also, a DDCP system can be provided, where a pigment-type coloring material same as the printing ink can be used, the transfer to printing paper can be performed, and moire and the like are not generated. Furthermore, according to the present invention, a large-size (A2/B2) digital direct color proof system capable of transferring an image to printing paper, using the same pigment-type coloring material as the printing ink and giving high approximation to a printed matter can be provided. The present invention is suitable for the system where a laser thin film transfer system is employed, a pigment coloring material is used and transfer to printing paper can be attained by real halftone dot recording. In addition, a multicolor image-forming material can be provided, in which, even when laser recording with high energy is performed using laser light in the multibeam two-dimensional arrangement, an image having good image quality, stable transfer density and excellent scratch resistance can be transferred to image-receiving sheet and in turn, a transfer image having good fine line fixing can be formed on printing paper. In the present invention, the lifting of transfer image is improved and furthermore, rough paper can be used as printing paper.

The entitle disclosure of each and every foreign patent application from which the benefit of foreign priority has been claimed in the present application is incorporated herein by reference, as if fully set forth herein.

While the invention has been described in detail and with reference to specific embodiments thereof, it will be apparent to one skilled in the art that various changes and modifications can be made therein without departing from the spirit and scope thereof.

What is claimed is:

1. A multicolor image-forming material of recording an image using an image-receiving sheet comprising a support having thereon at least an image-receiving layer, and thermal transfer sheets for forming four or more different colors each comprising a support having thereon at least a light-to-heat conversion layer and an image-forming layer, said image being recorded by superposing each said thermal transfer sheet and said image-receiving sheet such that the image-forming layer of the thermal transfer sheet and the image-receiving layer of the image-receiving layer come to face each other, irradiating laser light and transferring the image-forming layer in the region irradiated with the laser light onto the image-receiving layer of the image-receiving sheet, wherein the adhesive tape peeling strength on the image-receiving layer surface of said image-receiving sheet is from 800 to 20,000 mN/cm at room temperature.

2. The multicolor image-forming material as claimed in claim 1, wherein the adhesive tape peeling strength on the image-receiving layer surface of said image-receiving sheet is from 1,100 to 20,000 mN/cm at room temperature.

3. The multicolor image-forming material as claimed in claim 1, wherein the contact angle to water of the image-receiving layer of said image-receiving sheet is from 10.0° to 120.0°.

4. The multicolor image-forming material as claimed in any one of claims 1 to 3, wherein the contact angle to water of the image-receiving layer of said image-receiving sheet is from 30.0° to 120.0°.

5. The multicolor image-forming material as claimed in claim 1, wherein the contact angle to water of the image-receiving layer of said image-receiving sheet is from 30.0° to 85.0°.

6. The multicolor image-forming material as claimed in claim 1, wherein the adhesive tape peeling strength on the image-receiving layer surface of said image-receiving sheet is from 820 to 2,300 mN/cm at room temperature and the center line average surface roughness (Ra) on the image-receiving layer surface of said image-receiving sheet is from 0.01 to 0.3 μm.

7. The multicolor image-forming material as claimed in claim 6, wherein the center line average surface roughness (Ra) on the image-receiving layer surface of said image-receiving sheet is from 0.02 to 0.25 μm.

8. A multicolor image-forming material of recording an image using an image-receiving sheet comprising a support having thereon at least an image-receiving layer, and thermal transfer sheets for forming four or more different colors each comprising a support having thereon at least a light-to-heat conversion layer and an image-forming layer, said image being recorded by superposing each said thermal transfer sheet and said image-receiving sheet such that the image-forming layer of the thermal transfer sheet and the image-receiving layer of the image-receiving layer come to face each other, irradiating laser light and transferring the image-forming layer in the region irradiated with the laser light onto the image-receiving layer of the image-receiving sheet, wherein the residual solvent amount in said image-receiving sheet as a whole is from 5 to 100 μl/m².

9. The multicolor image-forming material as claimed in claim 8, wherein the residual solvent amount in said image-receiving sheet as a whole is from 20 to 60 μl/m².

10. The multicolor image-forming material as claimed in claim 8, wherein the image-receiving layer of said image-receiving sheet contains a polymer or a composition thereof having a glass transition temperature (Tg) of 6 to 57° C. under humidity conditioning to 50% RH at 25° C.

11. The multicolor image-forming material as claimed in claim 8, wherein the image-receiving layer of said image-receiving sheet contains a polymer or a composition thereof having an elongation at break of 1 to 130% at 25° C. and 50% RH.

12. The multicolor image-forming material as claimed in claim 1, wherein said transfer image is an image having a resolution of 2,400 dpi or more.

13. The multicolor image-forming material as claimed in claim 1, wherein said transfer image is an image having a resolution of 2,600 dpi or more.

14. The multicolor image-forming material as claimed in claim 1, wherein the area of said multicolor image recorded is in a size of 515 mm or more×728 mm or more.

15. The multicolor image-forming material as claimed in claim 1, wherein the area of said multicolor image recorded is in a size of 594 mm or more×841 mm or more.

16. The multicolor image-forming material as claimed in claim 1, wherein the ratio (OD_{I}/layer thickness (unit: μm)) between the optical density (OD_{I}) and the layer thickness of the image-forming layer of each thermal transfer sheet is 1.50 or more.

17. The multicolor image-forming material as claimed in claim 1, wherein the ratio (OD_{I}/layer thickness (unit: μm)) between the optical density (OD_{I}) and the layer thickness of the image-forming layer of each thermal transfer sheet is 1.80 or more.

18. The multicolor image-forming material as claimed in claim 1, wherein the contact angle to water of the image-forming layer of each thermal transfer sheet is from 7.0° to 120.0°.

19. The multicolor image-forming material as claimed in claim 1, wherein the ratio (OD_{I}/layer thickness (unit: μm)) between the optical density (OD_{I}) and the layer thickness of the image-forming layer of each thermal transfer sheet is 1.80 or more and the contact angle to water of the image-receiving sheet is 85° or less.

20. The multicolor image-forming material as claimed in claim 1, wherein the ratio (OD_{I}/layer thickness (unit: μm)) between the optical density (OD_{I}) and the layer thickness of the image-forming layer of each thermal transfer sheet is 2.50 or more.
